(19) United States
(12) Patent Application Publication
(10) Pub. No.: US 2026/0075802 A1
(43) Pub. Date: Mar. 12, 2026

(54) SEMICONDUCTOR DEVICE

(71) Applicant: SAMSUNG ELECTRONICS CO., LTD., Suwon-si (KR)

(72) Inventors: Minju KANG, Suwon-si (KR); Yongkwan KIM, Suwon-si (KR); Huijung KIM, Suwon-si (KR); Hyunjin LEE, Suwon-si (KR)

(73) Assignee: SAMSUNG ELECTRONICS CO., LTD., Suwon-si (KR)

(21) Appl. No.: 19/322,028

(22) Filed: Sep. 8, 2025

(30) Foreign Application Priority Data
Sep. 9, 2024 (KR) 10-2024-0122583

(51) Int. Cl. H10B 12/00

(52) U.S. Cl. CPC H10B 12/315; H10B 12/05

(57) ABSTRACT

A semiconductor device may include: a bit line extending in a first horizontal direction; a plurality of vertical channel patterns on the bit line and separated from each other in the first horizontal direction; two word lines extending in a second horizontal direction between adjacent vertical channel patterns of the plurality of vertical channel patterns, the second horizontal direction intersecting the first horizontal direction; a plurality of contact plugs contacting upper portions of the plurality of vertical channel patterns; and an isolation insulating structure between the plurality of contact plugs, wherein the isolation insulating structure includes: a lower insulating pattern; an upper insulating pattern on the lower insulating pattern; and an insulating spacer on a sidewall of the upper insulating pattern and an upper sidewall of the lower insulating pattern.

### CROSS-REFERENCE TO RELATED APPLICATION

This application is based on and claims priority under 35 U.S.C. § 119 to Korean Patent Application No. 10-2024-0122583, filed on Sep. 9, 2024, in the Korean Intellectual Property Office, the disclosure of which is incorporated by reference herein in its entirety.

### BACKGROUND

The disclosure relates to a semiconductor device, and more particularly, to a semiconductor device including a vertical channel transistor.

Increasing the integration density of integrated circuit devices may help obtaining high performance and economic feasibility. In particular, the integration density of memory devices is an important factor in determining the economic feasibility of products. The integration density of two-dimensional (2D) memory devices is mainly determined by the area of a memory cell unit and is thus greatly influenced by the level of a micropatterning technique. However, because expensive equipment is needed to form micropatterns and the area of a chip die is limited, the integration density of 2D memory devices is still limited, although it is increasing.

### SUMMARY

One or more embodiments disclosure provide a semiconductor device including a vertical channel transistor that may have high electrical reliability and high device stability.

Embodiments of the disclosure are not limited to what is mentioned above, and other aspects that have not been mentioned will be clearly understood by one of skill in the art from the descriptions below.

According to an aspect of the disclosure, a semiconductor device includes: a bit line extending in a first horizontal direction; a plurality of vertical channel patterns on the bit line and separated from each other in the first horizontal direction; two word lines extending in a second horizontal direction between adjacent vertical channel patterns of the plurality of vertical channel patterns, the second horizontal direction intersecting the first horizontal direction; a plurality of contact plugs contacting upper portions of the plurality of vertical channel patterns; and an isolation insulating structure between the plurality of contact plugs, wherein the isolation insulating structure includes: a lower insulating pattern; an upper insulating pattern on the lower insulating pattern; and an insulating spacer on a sidewall of the upper insulating pattern and an upper sidewall of the lower insulating pattern. Upper widths of the plurality of contact plugs in the first horizontal direction may be less than lower widths of the plurality of contact plugs in the first horizontal direction, and an upper width of the isolation insulating structure in the first horizontal direction may be greater than a lower width of the isolation insulating structure in the first horizontal direction.

According to an aspect of the disclosure, a semiconductor device includes: a bit line extending in a first horizontal direction; a plurality of vertical channel patterns on the bit line and separated from each other in the first horizontal direction; two word lines extending in a second horizontal direction between adjacent vertical channel patterns of the plurality of vertical channel patterns, the second horizontal direction intersecting the first horizontal direction; a plurality of contact plugs contacting upper portions of the plurality of vertical channel patterns; and an isolation insulating structure between the plurality of contact plugs, wherein the isolation insulating structure includes: a lower insulating pattern having a first width in the first horizontal direction; and an upper insulating pattern on the lower insulating pattern and having a second width greater than the first width. A bottom surface of the lower insulating pattern may be curved.

According to an aspect of the disclosure, a semiconductor device includes: a bit line extending in a first horizontal direction; a plurality of vertical channel patterns on the bit line and separated from each other in the first horizontal direction; two word lines extending in a second horizontal direction between first vertical channel pattern and second vertical channel pattern of the plurality of vertical channel patterns, the first vertical channel pattern and the second vertical channel pattern being adjacent, the second horizontal direction intersecting the first horizontal direction; a back gate electrode extending in the second horizontal direction between the second vertical channel pattern and a third vertical channel pattern of the plurality of vertical channel patterns, the second vertical channel pattern and the third vertical channel pattern being adjacent; a plurality of contact plugs contacting upper portions of the plurality of vertical channel patterns; an isolation insulating structure between the plurality of contact plugs; and a capacitor structure on the plurality of contact plugs and the isolation insulating structure. The plurality of contact plugs may include: a first conductive pattern including doped polysilicon; a second conductive pattern on the first conductive pattern and including metal silicide; and a third conductive pattern on the second conductive pattern and including metal. The isolation insulating structure may include: a lower insulating pattern; an upper insulating pattern on the lower insulating pattern; and an insulating spacer on a sidewall of the upper insulating pattern and an upper sidewall of the lower insulating pattern.

### BRIEF DESCRIPTION OF THE DRAWINGS

The above and/or other aspects will be more clearly understood from the following detailed description taken in conjunction with the accompanying drawings, in which:

FIG. 1 is a planar layout illustrating a semiconductor device according to one or more embodiments;

FIG. 2 is a cross-sectional view taken along line X1-X1′ in FIG. 1 according to one or more embodiments;

FIG. 3 is an enlarged view of a region CX in FIG. 2 according to one or more embodiments;

FIG. 4 is a cross-sectional view of semiconductor devices according to one or more embodiments;

FIG. 5 is a cross-sectional view of semiconductor devices according to one or more embodiments;

FIG. 6 is a cross-sectional view of semiconductor devices according to one or more embodiments;

FIG. 7 is a cross-sectional view of semiconductor devices according to one or more embodiments;

FIG. 8A is a diagram of a sequential stage in a method of manufacturing a semiconductor device, according to one or more embodiments;

FIG. 8B is a diagram of a sequential stage in a method of manufacturing a semiconductor device, according to one or more embodiments;

FIG. 9A is a diagram of a sequential stage in a method of manufacturing a semiconductor device, according to one or more embodiments;

FIG. 9B is a diagram of a sequential stage in a method of manufacturing a semiconductor device, according to one or more embodiments;

FIG. 10A is a diagram of a sequential stage in a method of manufacturing a semiconductor device, according to one or more embodiments;

FIG. 10B is a diagram of a sequential stage in a method of manufacturing a semiconductor device, according to one or more embodiments;

FIG. 11A is a diagram of a sequential stage in a method of manufacturing a semiconductor device, according to one or more embodiments;

FIG. 11B is a diagram of a sequential stage in a method of manufacturing a semiconductor device, according to one or more embodiments;

FIG. 12A is a diagram of a sequential stage in a method of manufacturing a semiconductor device, according to one or more embodiments;

FIG. 12B is a diagram of a sequential stage in a method of manufacturing a semiconductor device, according to one or more embodiments;

FIG. 13A is a diagram of a sequential stage in a method of manufacturing a semiconductor device, according to one or more embodiments;

FIG. 13B is a diagram of a sequential stage in a method of manufacturing a semiconductor device, according to one or more embodiments;

FIG. 14A is a diagram of a sequential stage in a method of manufacturing a semiconductor device, according to one or more embodiments;

FIG. 14B is a diagram of a sequential stage in a method of manufacturing a semiconductor device, according to one or more embodiments;

FIG. 15A is a diagram of a sequential stage in a method of manufacturing a semiconductor device, according to one or more embodiments;

FIG. 15B is a diagram of a sequential stage in a method of manufacturing a semiconductor device, according to one or more embodiments;

FIG. 16A is a diagram of a sequential stage in a method of manufacturing a semiconductor device, according to one or more embodiments;

FIG. 16B is a diagram of a sequential stage in a method of manufacturing a semiconductor device, according to one or more embodiments;

FIG. 17A is a diagram of a sequential stage in a method of manufacturing a semiconductor device, according to one or more embodiments;

FIG. 17B is a diagram of a sequential stage in a method of manufacturing a semiconductor device, according to one or more embodiments;

FIG. 18A is a diagram of a sequential stage in a method of manufacturing a semiconductor device, according to one or more embodiments;

FIG. 18B is a diagram of a sequential stage in a method of manufacturing a semiconductor device, according to one or more embodiments;

FIG. 19A is a diagram of a sequential stage in a method of manufacturing a semiconductor device, according to one or more embodiments;

FIG. 19B is a diagram of a sequential stage in a method of manufacturing a semiconductor device, according to one or more embodiments;

FIG. 20A is a diagram of a sequential stage in a method of manufacturing a semiconductor device, according to one or more embodiments;

FIG. 20B is a diagram of a sequential stage in a method of manufacturing a semiconductor device, according to one or more embodiments;

FIG. 21A is a diagram of a sequential stage in a method of manufacturing a semiconductor device, according to one or more embodiments;

FIG. 21B is a diagram of a sequential stage in a method of manufacturing a semiconductor device, according to one or more embodiments;

FIG. 22A is a diagram of a sequential stage in a method of manufacturing a semiconductor device, according to one or more embodiments;

FIG. 22B is a diagram of a sequential stage in a method of manufacturing a semiconductor device, according to one or more embodiments;

FIG. 23A is a diagram of a sequential stage in a method of manufacturing a semiconductor device, according to one or more embodiments;

FIG. 23B is a diagram of a sequential stage in a method of manufacturing a semiconductor device, according to one or more embodiments;

FIG. 24A is a diagram of a sequential stage in a method of manufacturing a semiconductor device, according to one or more embodiments;

FIG. 24B is a diagram of a sequential stage in a method of manufacturing a semiconductor device, according to one or more embodiments;

FIG. 25 is a diagram of a sequential stage in a method of manufacturing a semiconductor device, according to one or more embodiments;

FIG. 26 is a diagram of a sequential stage in a method of manufacturing a semiconductor device, according to one or more embodiments;

FIG. 27 is a diagram of a sequential stage in a method of manufacturing a semiconductor device, according to one or more embodiments;

FIG. 28 is a diagram of a sequential stage in a method of manufacturing a semiconductor device, according to one or more embodiments;

FIG. 29 is a diagram of a sequential stage in a method of manufacturing a semiconductor device, according to one or more embodiments;

FIG. 30 is a diagram of a sequential stage in a method of manufacturing a semiconductor device, according to one or more embodiments;

FIG. 31 is a diagram of a sequential stage in a method of manufacturing a semiconductor device, according to one or more embodiments;

FIG. 32 is a diagram of a sequential stage in a method of manufacturing a semiconductor device, according to one or more embodiments; and

FIG. 33 is a block diagram of a system including a semiconductor device, according to one or more embodiments.

### DETAILED DESCRIPTION

Hereinafter, example embodiments are described in detail with reference to the accompanying drawings.

In the specification, spatially relative terms such as “top”, “bottom”, “upper”, “lower”, “up”, “down”, “horizontal,” “vertical” etc. are used to easily explain the positional relationship of each component when viewed from a direction depicted in the drawings. Therefore, spatially relative terms indicating the positional relationship of each component may be understood differently when viewed from a direction other than the direction depicted in the drawings.

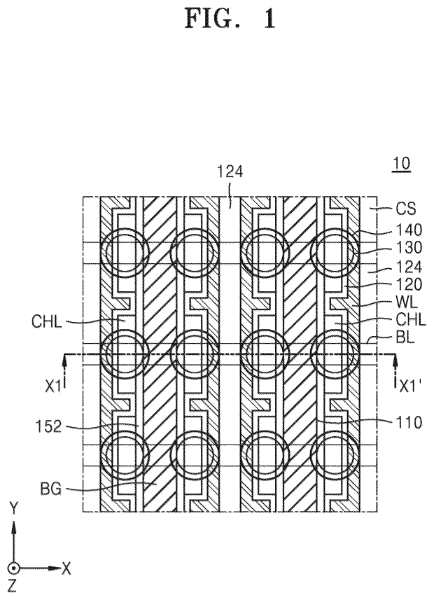

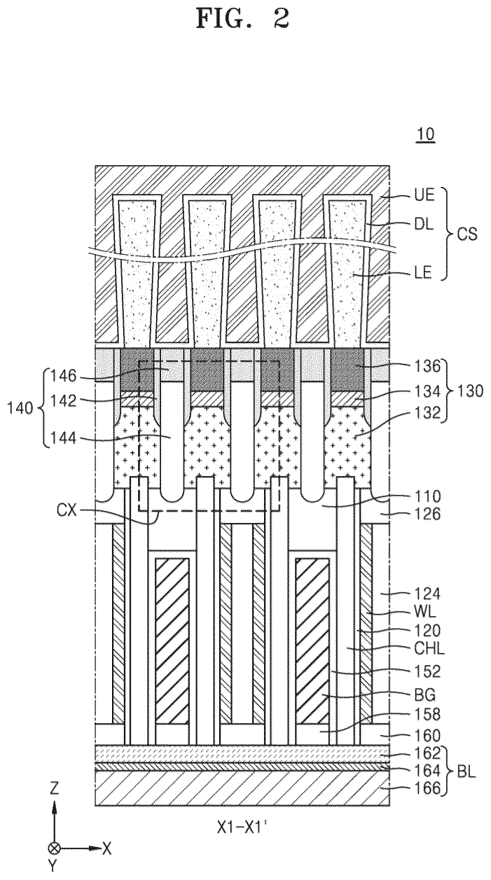

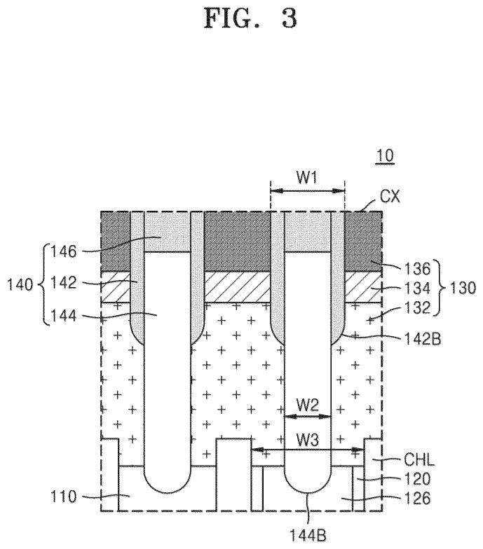

FIG. 1 is a planar layout illustrating a semiconductor device according to one or more embodiments. FIG. 2 is a cross-sectional view taken along line X1-X1′ in FIG. 1. FIG. 3 is an enlarged view of a region CX in FIG. 2.

Referring to FIGS. 1 to 3, a semiconductor device 10 may include a plurality of bit lines BL, which extend lengthwise in a first horizontal direction (an X direction) and are repeatedly arranged spaced apart from each other (separated) in a second horizontal direction (a Y direction) crossing (intersecting) the first horizontal direction (the X direction).

A plurality of vertical channel patterns CHL may be arranged above each of the bit lines BL. A plurality of contact plugs 130 may be respectively arranged above the vertical channel patterns CHL. The vertical channel patterns CHL may be between each bit line BL and the contact plugs 130 and may be repeatedly arranged spaced apart from one another in the first horizontal direction (the X direction) and the second horizontal direction (the Y direction).

The bit line BL may include metal, conductive metal nitride, metal silicide, doped polysilicon, or a combination thereof. In one or more embodiments, the bit line BL may include a first conductive line 162, a second conductive line 164, and a third conductive line 166, which are sequentially stacked below the vertical channel patterns CHL. For example, the first conductive line 162 may include doped polyslilicon, the second conductive line 164 may include metal silicide, and the third conductive line 166 may include metal, but embodiments are not limited thereto.

Each of the vertical channel patterns CHL may have an end connected to the bit line BL and an opposite end connected to one of the contact plugs 130. In other words, each of the vertical channel patterns CHL may be in contact with one bit line BL and one contact plug 130.

In one or more embodiments, the vertical channel patterns CHL may include silicon, e.g., single-crystalline silicon, polycrystalline silicon, or amorphous silicon. In one or more embodiments, the vertical channel patterns CHL may include at least one selected from the group consisting of Ge, SiGe, SiC, GaAs, InAs, and InP.

The contact plugs 130 may be separated from the bit line BL with the vertical channel patterns CHL between the contact plugs 130 and the bit line BL in a vertical direction (a Z direction). The contact plugs 130 may be spaced apart from one another in the first horizontal direction (the X direction) and the second horizontal direction (the Y direction) in a matrix. The contact plugs 130 may be respectively connected to the vertical channel patterns CHL.

The contact plugs 130 may include metal, conductive metal nitride, metal silicide, doped polysilicon, or a combination thereof. For example, each of the contact plugs 130 may include Ti, TiN, Ta, TaN, Mo, Ru, W, WN, Co, Ni, TiSi, TiSiN, WSi, WSiN, TaSi, TaSiN, RuTiN, CoSi, NiSi, doped silicon, or a combination thereof. In one or more embodiments, each of the contact plugs 130 may include a first conductive pattern 132, a second conductive pattern 134, and a third conductive pattern 136, which are sequentially stacked on one of the vertical channel patterns CHL. For example, the first conductive pattern 132 may include doped polysilicon, the second conductive pattern 134 may include metal silicide, and the third conductive pattern 136 may include metal, but embodiments are not limited thereto.

In the semiconductor device 10, an upper width of each of the contact plugs 130 in the first horizontal direction (the X direction) may be less than a lower width thereof in the first horizontal direction (the X direction). Specifically, the maximum width of the first conductive pattern 132 in the first horizontal direction (the X direction) may be greater than the width of the second conductive pattern 134 in the first horizontal direction (the X direction). The width of the second conductive pattern 134 in the first horizontal direction (the X direction) may be substantially the same as the width of the third conductive pattern 136 in the first horizontal direction (the X direction).

In one or more embodiments, the bottom surface of the first conductive pattern 132 may have a convex-concave (pitted) shape which is in contact with the top surface and both sidewalls of one of the vertical channel patterns CHL. Alternatively, the bottom surface of the first conductive pattern 132 may have a flat shape.

Each of the contact plugs 130 may be in contact with one of the vertical channel patterns CHL through an isolation insulating structure 140.

In the semiconductor device 10, the isolation insulating structure 140 may include a lower insulating pattern 144, an upper insulating pattern 146 on the lower insulating pattern 144, and an insulating spacer 142 arranged along the entire sidewall of the upper insulating pattern 146 and an upper sidewall of the lower insulating pattern 144.

In one or more embodiments, the insulating spacer 142 may include the same material as the upper insulating pattern 146. For example, the insulating spacer 142 and the upper insulating pattern 146 may include, but not limited to, an SiN film, an SiOC film, an SiOCN film, an SiCN film, or an SiBN film. The insulating spacer 142 and the upper insulating pattern 146 may include an insulating material having excellent etching resistance to a wet etching process.

In one or more embodiments, the lower insulating pattern 144 may include a different material than the upper insulating pattern 146. For example, the lower insulating pattern 144 may include a silicon oxide film, a low-k film, or a combination thereof. The low-k film refers to a film having a lower dielectric constant than a silicon oxide film. For example, the low-k film may include an SiOC film or an SiCOH film but is not limited thereto. The lower insulating pattern 144 may include an insulating material suppressing the occurrence of parasitic capacitance.

In the semiconductor device 10, an upper width W1 of the isolation insulating structure 140 in the first horizontal direction (the X direction) may be greater than a lower width W2 thereof in the first horizontal direction (the X direction).

The lower width W2 of the isolation insulating structure 140 may correspond to the horizontal width of the lower insulating pattern 144 and may be significantly less than a distance W3 between two adjacent vertical channel patterns CHL. Accordingly, the isolation insulating structure 140 may be prevented from coming into contact the vertical channel patterns CHL due to an undesirable non-uniform distribution in a process of forming the isolation insulating structure 140.

The upper width W1 of the isolation insulating structure 140 may correspond to the sum of the horizontal widths of the insulating spacer 142 and the upper insulating pattern 146 and may be greater than the lower width W2 of the isolation insulating structure 140. Accordingly, the insulating spacer 142 and the upper insulating pattern 146 may efficiently function as a barrier that prevents penetration of an etching solution in a wet etching process performed after the isolation insulating structure 140 is formed.

In one or more embodiments, a length of the lower insulating pattern 144 in the vertical direction (the Z direction) may be greater than a length of the upper insulating pattern 146 in the vertical direction (the Z direction). A length of the insulating spacer 142 in the vertical direction (the Z direction) may be greater than the length of the upper insulating pattern 146 in the vertical direction (the Z direction).

In one or more embodiments, the vertical level of the topmost surface of the upper insulating pattern 146 may be the same as the vertical level of the topmost surface of the insulating spacer 142, and a bottom surface 142B of the insulating spacer 142 may be oblique (tapered). The vertical level of the bottommost (bottom) surface of the lower insulating pattern 144 may be lower than the vertical level of the topmost (top) surface of each of the vertical channel patterns CHL. A bottom surface 144B of the lower insulating pattern 144 may be round (curved).

In the semiconductor device 10, the first conductive pattern 132 of each of the contact plugs 130 may be in contact with the insulating spacer 142 and the lower insulating pattern 144. The second conductive pattern 134 and the third conductive pattern 136 of each contact plug 130 may be in contact with the insulating spacer 142 but not with the lower insulating pattern 144.

A plurality of back gate electrodes BG and a plurality of word lines WL may be arranged above the bit line BL. The back gate electrodes BG and the word lines WL may extend lengthwise in the second horizontal direction (the Y direction) between the bit line BL and the contact plugs 130. The back gate electrodes BG and the word lines WL may be spaced apart from each other in the first horizontal direction (the X direction).

Among the back gate electrodes BG and the word lines WL arranged above the bit line BL in parallel in the first horizontal direction (the X direction), one back gate electrode BG may be alternately arranged with a pair of word lines WL, and the back gate electrode BG may be separated from the pair of word lines WL with one vertical channel pattern CHL between the back gate electrode BG and the pair of word lines WL. In other words, the plurality of word lines WL may be arranged such that a pair of adjacent word lines WL are between two adjacent back gate electrodes BG.

One back gate electrode BG may extend lengthwise in the second horizontal direction (the Y direction) between a pair of vertical channel patterns CHL adjacent to each other in the first horizontal direction (the X direction). The plurality of back gate electrodes BG may be apart from the bit line BL and the contact plugs 130 in the vertical direction (the Z direction).

The back gate electrodes BG may include metal, conductive metal nitride, doped polysilicon, or a combination thereof. For example, each of the back gate electrodes BG may include, but not limited to, Ti, TiN, Ta, TaN, Mo, Ru, W, WN, TiSiN, WSiN, doped polysilicon, or a combination thereof.

The plurality of word lines WL may include metal, conductive metal nitride, or a combination thereof. For example, the word lines WL may include, but not limited to, Ti, TiN, Ta, TaN, Mo, Ru, W, WN, TiSiN, WSiN, or a combination thereof.

The semiconductor device 10 may include a plurality of back gate dielectric films 152 respectively covering the surfaces of the back gate electrodes BG. Each of the back gate dielectric films 152 may be between a pair of vertical channel patterns CHL respectively at opposite sides of one back gate electrode BG between the vertical channel patterns CHL. Each of the back gate dielectric films 152 may be in contact with the pair of vertical channel patterns CHL.

A first capping insulating pattern 110 may be between a pair of adjacent vertical channel patterns CHL and between the top surface of one back gate dielectric film 152 and a plurality of contact plugs 130. A second capping insulating pattern 158 may be between a pair of adjacent vertical channel patterns CHL and between the back gate electrode BG and the bit line BL. The first capping insulating pattern 110, the back gate electrode BG, and the second capping insulating pattern 158 may overlap one another in the vertical direction (the Z direction).

The first capping insulating pattern 110 and the second capping insulating pattern 158 may each include a silicon oxide film, a silicon nitride film, or a combination thereof. In one or more embodiments, the first capping insulating pattern 110 and the second capping insulating pattern 158 may include different materials from each other. For example, the first capping insulating pattern 110 may include a silicon oxide film, and the second capping insulating pattern 158 may include a silicon nitride film. In one or more embodiments, the first capping insulating pattern 110 and the second capping insulating pattern 158 may include the same material. For example, the first capping insulating pattern 110 and the second capping insulating pattern 158 may include a silicon oxide film or a silicon nitride film.

Each of the word lines WL may be apart from the bit line BL and each of the contact plugs 130 in the vertical direction (the Z direction). A pair of word lines WL may be between two adjacent back gate electrodes BG in the first horizontal direction (the X direction). The pair of (two) word lines WL may be apart in the first horizontal direction (the X direction) from a back gate electrode BG adjacent thereto with one vertical channel pattern CHL between the pair of word lines WL and the back gate electrode BG.

A sandwich pattern 124 may be between the pair of word lines WL between a pair of adjacent vertical channel patterns CHL. A first buried insulating pattern 126 may be between the pair of word lines WL and a plurality of contact plugs 130. A second buried insulating pattern 160 may be between the pair of word lines WL and the bit line BL. The pair of word lines WL, the first buried insulating pattern 126, and the second buried insulating pattern 160, which are between a pair of adjacent vertical channel patterns CHL, may overlap one another in the vertical direction (the Z direction).

The pair of word lines WL may be apart from the contact plugs 130 with the first buried insulating pattern 126 between the pair of word lines WL and the contact plugs 130. The pair of word lines WL may be apart from the bit line BL with the second buried insulating pattern 160 between the pair of word lines WL and the bit line BL. The length of the second capping insulating pattern 158 in the vertical direction (the Z direction) may be substantially the same as or similar to the length of the second buried insulating pattern 160 in the vertical direction (the Z direction).

For example, the sandwich pattern 124, the first buried insulating pattern 126, and the second buried insulating pattern 160 may each include a silicon oxide film, a silicon nitride film, or a combination thereof. In one or more embodiments, the sandwich pattern 124, the first buried insulating pattern 126, and the second buried insulating pattern 160 may include the same or similar materials. In one or more embodiments, at least one selected from the group consisting of the sandwich pattern 124, the first buried insulating pattern 126, and the second buried insulating pattern 160 may include a different material than the others. For example, each of the sandwich pattern 124, the first buried insulating pattern 126, and the second buried insulating pattern 160 may include a silicon nitride film but is not limited thereto.

A gate dielectric film 120 may be between each of the plurality of word lines WL and a vertical channel pattern CHL adjacent to each word line WL. A pair of gate dielectric films 120 may be between a pair of adjacent vertical channel patterns CHL, and a pair of word lines WL may be between the pair of gate dielectric films 120. Each of the gate dielectric films 120 may include an end in contact with the bit line BL and an opposite end in contact with one of the contact plugs 130.

In one or more embodiments, the gate dielectric film 120 and the back gate dielectric film 152 may each include a silicon oxide film, a high-k film, or a combination thereof. The high-k film may refer to a dielectric film having a higher dielectric constant than a silicon oxide film. In embodiments, the gate dielectric film 120 and the back gate dielectric film 152 may each include at least one material selected from the group consisting of silicon oxide, hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), bismuth iron oxide (BFO), strontium titanium oxide (SrTiO), yttrium oxide (YO), aluminum oxide (AlO), and lead scandium tantalum oxide (PbScTaO).

A plurality of back gate electrodes BG, a plurality of word lines WL, a plurality of channel patterns CHL, a plurality of back gate dielectric films 152, and a plurality of gate dielectric films 120 may be between the bit line BL and the contact plugs 130 and may form a plurality of vertical channel transistors.

A capacitor structure CS may be arranged on the contact plugs 130 and the isolation insulating structure 140. The capacitor structure CS may include a plurality of lower electrodes LE, a capacitor dielectric film DL conformally covering the surfaces of the lower electrodes LE, and an upper electrode UE covering the lower electrodes LE with the capacitor dielectric film DL between the upper electrode UE and the lower electrodes LE. Each of the lower electrodes LE may be connected to one of the vertical channel patterns CHL through one of the contact plugs 130. The third conductive pattern 136 of each of the contact plugs 130 may function as a landing pad with which one of the lower electrodes LE is in contact.

According to one or more embodiments of the disclosure, even when elements required to form a vertical channel transistor are arranged in a relatively narrow and long space with the miniaturization and high integration density of the semiconductor device 10, an element, e.g., the isolation insulating structure 140, of the vertical channel transistor may be prevented from coming into contact with the vertical channel patterns CHL due to undesirable non-uniform distribution in a process of forming the isolation insulating structure 140, and accordingly, a structure capable of sufficiently securing the contact area between the vertical channel patterns CHL and the contact plugs 130 may be provided.

Eventually, the semiconductor device 10 of one or more embodiments of the disclosure may have high electrical reliability and device stability by arranging the isolation insulating structure 140, which has the upper width W1 different from the lower width W2, between the contact plugs 130 adjacent to each other.

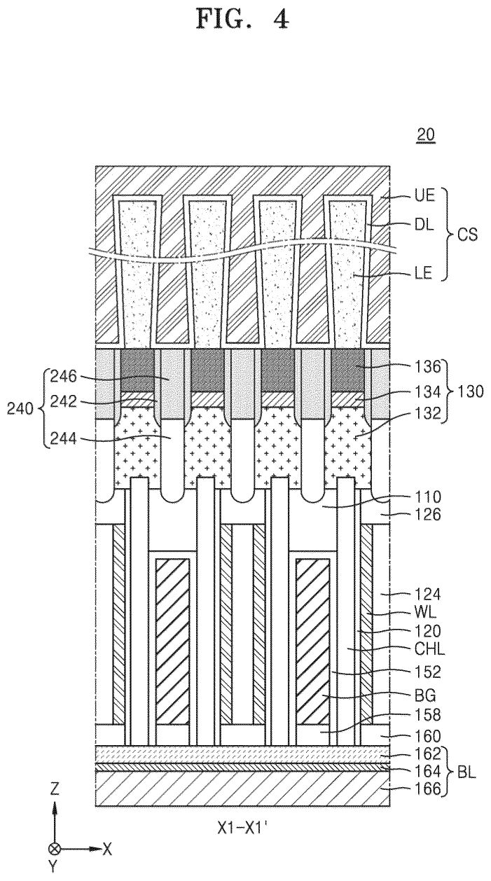

FIGS. 4 to 7 are cross-sectional views of semiconductor devices according to one or more embodiments.

The elements of semiconductor devices 20, 30, 40, and 50 and the materials of the elements described below are mostly and substantially the same as or similar to those described above with reference to FIGS. 1 to 3. Therefore, for the convenience of description, the differences from the semiconductor device 10 are mainly described below.

Referring to FIG. 4, the semiconductor device 20 may include an isolation insulating structure 240 separating the contact plugs 130 from each other.

In the semiconductor device 20 of the present embodiment, the isolation insulating structure 240 may include a lower insulating pattern 244, an upper insulating pattern 246 on the lower insulating pattern 244, and an insulating spacer 242 arranged on the entire sidewall of the upper insulating pattern 246 and an upper sidewall of the lower insulating pattern 244.

In the semiconductor device 20 of the present embodiment, the vertical level of the topmost surface of the upper insulating pattern 246 may be the same as the vertical level of the topmost surface of the insulating spacer 242, and the vertical level of the bottommost surface of the upper insulating pattern 246 may be higher than the vertical level of the bottommost surface of the insulating spacer 242. The vertical level of the bottommost surface of the upper insulating pattern 246 may be lower than the vertical level of the topmost surface of the first conductive pattern 132 of each of the contact plugs 130.

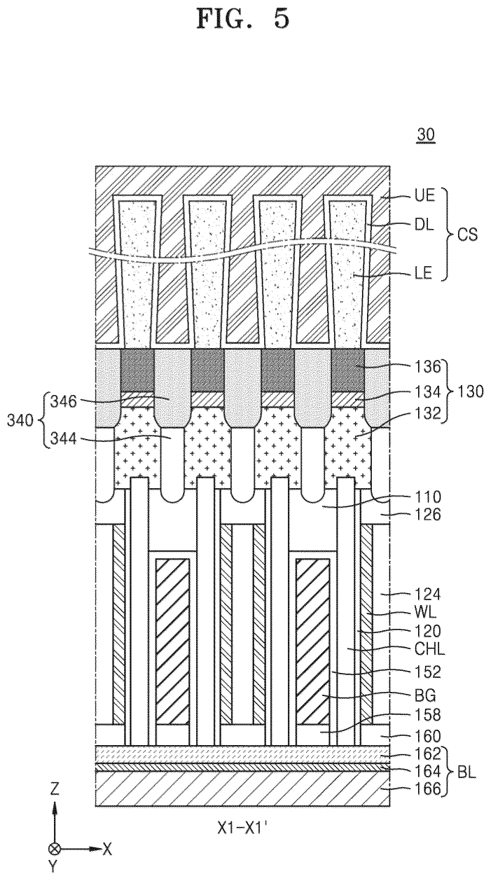

Referring to FIG. 5, the semiconductor device 30 may include an isolation insulating structure 340 separating the contact plugs 130 from each other.

In the semiconductor device 30 of the present embodiment, the isolation insulating structure 340 may include a lower insulating pattern 344 and an upper insulating pattern 346 on the lower insulating pattern 344. The upper width of the isolation insulating structure 340 in the first horizontal direction (the X direction) may be greater than the lower width of the isolation insulating structure 340 in the first horizontal direction (the X direction). The lower width of the isolation insulating structure 340 may correspond to the horizontal width of the lower insulating pattern 344, and the upper width of the isolation insulating structure 340 may correspond to the horizontal width of the upper insulating pattern 346. The lower insulating pattern 344 may include a material different from the material of the upper insulating pattern 346.

In the semiconductor device 30 of the present embodiment, the first conductive pattern 132 of each of the contact plugs 130 may be in contact with the lower insulating pattern 344 and the upper insulating pattern 346 of the isolation insulating structure 340. The second conductive pattern 134 and the third conductive pattern 136 of each of the contact plugs 130 may be in contact with the upper insulating pattern 346 but may not be in contact with the lower insulating pattern 344.

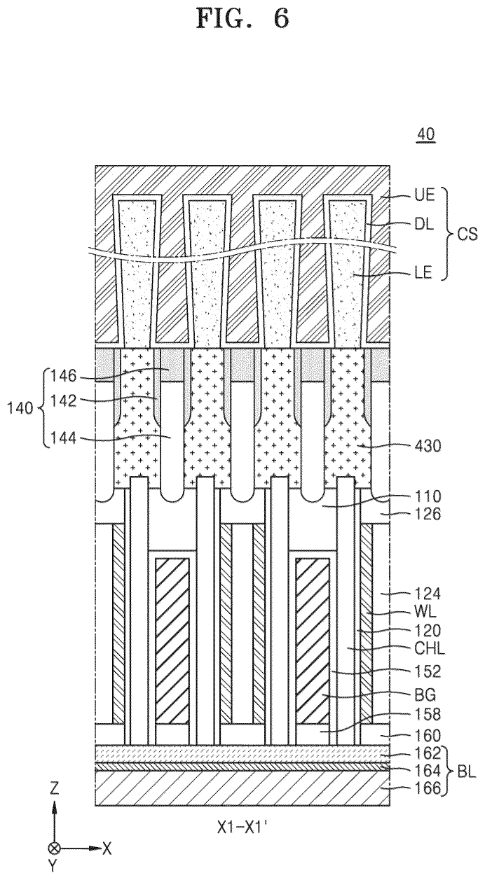

Referring to FIG. 6, the semiconductor device 40 may include a plurality of contact plugs 430 which pass through the isolation insulating structure 140 and are respectively in contact with a plurality of vertical channel patterns CHL.

In the semiconductor device 40 of the present embodiment, the contact plugs 430 may include a single structure of doped polysilicon. The upper width of each of the contact plugs 430 in the first horizontal direction (the X direction) may be less than the lower width of each contact plug 430 in the first horizontal direction (the X direction). The contact plugs 430 may be in contact with the insulating spacer 142 and the lower insulating pattern 144 of the isolation insulating structure 140.

In the semiconductor device 40 of the present embodiment, the bottom surface of each of the contact plugs 430 may have a convex-concave shape which is in contact with the top surface and both sidewalls of one of the vertical channel patterns CHL. Alternatively, the bottom surface of each of the contact plugs 430 may have a flat shape.

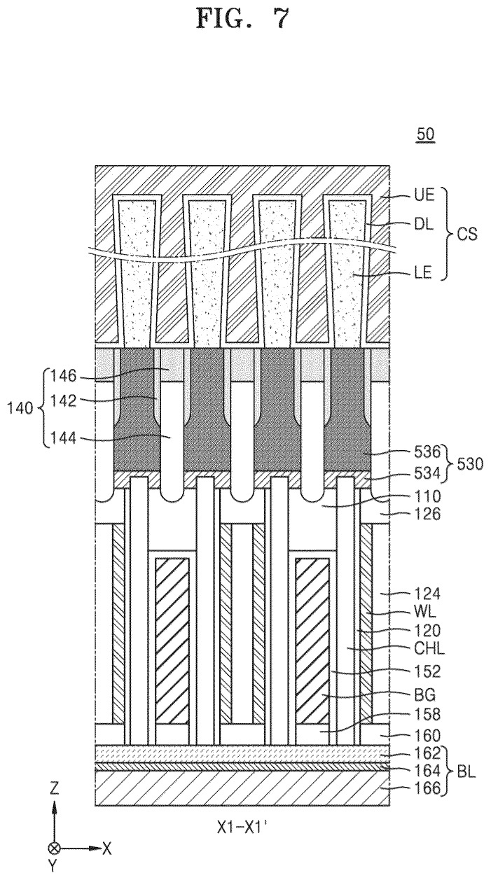

Referring to FIG. 7, the semiconductor device 50 may include a plurality of contact plugs 530 which pass through the isolation insulating structure 140 and are respectively in contact with a plurality of vertical channel patterns CHL.

In the semiconductor device 50 of the present embodiment, each of the contact plugs 530 may include a lower conductive pattern 534 and an upper conductive pattern 536, which are sequentially stacked on one of the vertical channel patterns CHL. For example, the lower conductive pattern 534 may include metal silicide, and the upper conductive pattern 536 may include metal. However, embodiments of the disclosure are not limited thereto.

In the semiconductor device 50 of the present embodiment, the upper width of each of the contact plugs 530 in the first horizontal direction (the X direction) may be less than the lower width of each contact plug 530 in the first horizontal direction (the X direction). Specifically, the upper width of the upper conductive pattern 536 may be less than the lower width of the upper conductive pattern 536. The width of the lower conductive pattern 534 in the first horizontal direction (the X direction) may be substantially the same as the lower width of the upper conductive pattern 536 in the first horizontal direction (the X direction).

In the semiconductor device 50 of the present embodiment, the bottom surface of the lower conductive pattern 534 may have a convex-concave shape which is in contact with the top surface and both sidewalls of one of the vertical channel patterns CHL. Alternatively, the bottom surface of the lower conductive pattern 534 may have a flat shape.

In the semiconductor device 50 of the present embodiment, the upper conductive pattern 536 may be in contact with the insulating spacer 142 and the lower insulating pattern 144 of the isolation insulating structure 140. The lower conductive pattern 534 may be in contact with the lower insulating pattern 144 of the isolation insulating structure 140 but may not be in contact with the insulating spacer 142.

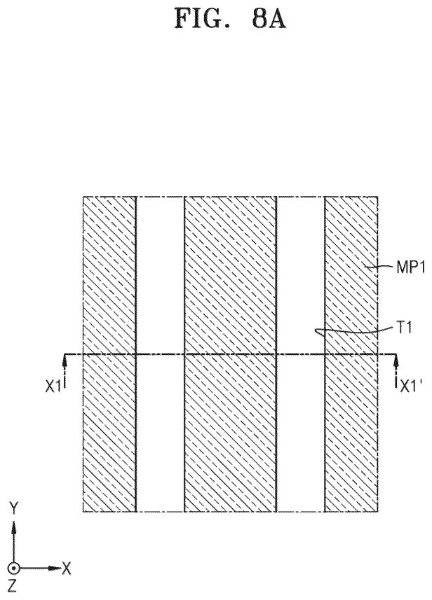

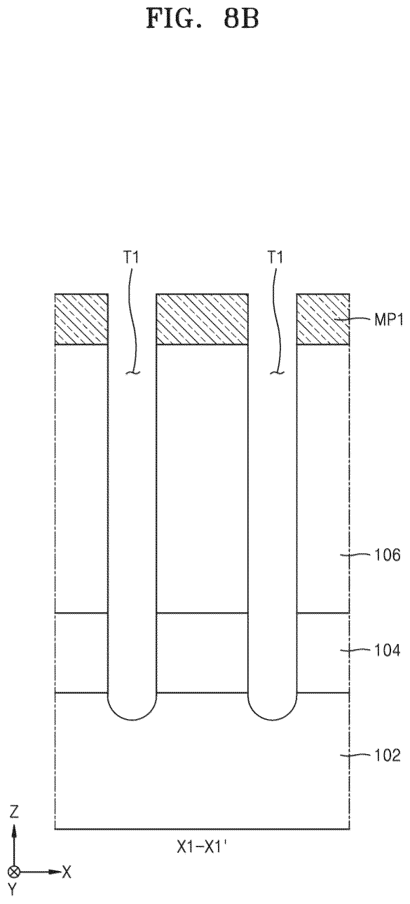

FIGS. 8A to 32 are diagrams of sequential stages in a method of manufacturing a semiconductor device, according to one or more embodiments.

In detail, FIGS. 8A, 9A, 10A, . . . , 23A, and 24A are planar layouts illustrating some elements of a semiconductor device in sequential stages in a method of manufacturing the semiconductor device. In the drawings, portions marked with dashed lines are illustrated to promote understanding although the portions are at the bottom and not shown from the top.

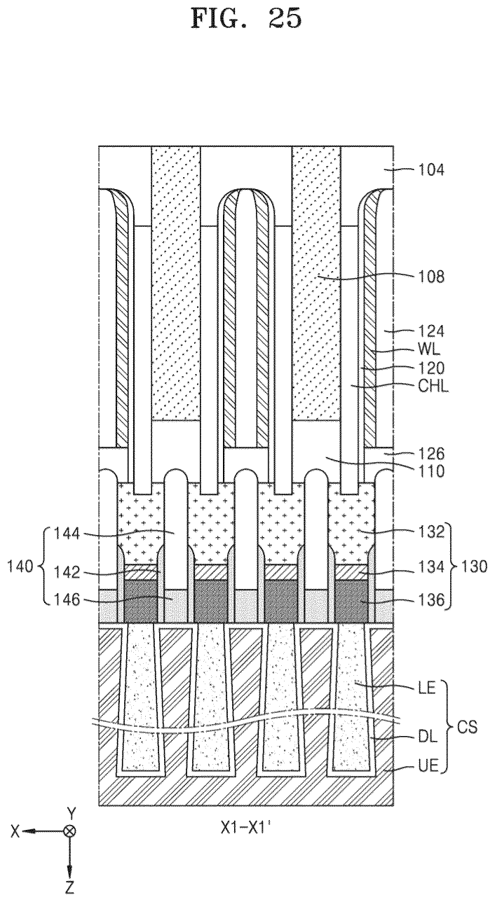

FIGS. 8B, 9B, 10B, . . . , 23B, and 24B and FIGS. 25 to 32 are cross-sectional views of sequential stages, taken along line X1-X1′ in FIG. 1, in the method of manufacturing a semiconductor device, wherein FIGS. 8B, 9B, 10B, . . . , 23B, and 24B are cross-sectional views taken along line X1-X1′ in FIGS. 8A, 9A, 10A, . . . , 23A, and 24A, respectively.

In FIGS. 1 to 3 and 8A to 32, like elements are denoted by like reference characters, and redundant descriptions thereof are omitted below.

Referring to FIGS. 8A and 8B, a substrate structure including a substrate 102, a buried insulating layer 104, and an active layer 106 may be prepared.

The substrate structure may correspond to a silicon-on-insulator (SOI) substrate. The substrate 102 may include a silicon substrate. The buried insulating layer 104 may include a silicon oxide film. The active layer 106 may include at least one selected from the group consisting of Ge, SiGe, SiC, GaAs, InAs, and InP. In one or more embodiments, the active layer 106 may include an impurity-doped well or an impurity-doped structure.

A mask pattern MP1 may be formed on the active layer 106 of the substrate structure. The mask pattern MP1 may include a silicon nitride film. In one or more embodiments, a silicon oxide film may be between the active layer 106 and the mask pattern MP1.

A plurality of first trenches T1 may be formed by etching some portions of the substrate structure by using the mask pattern MP1 as an etch mask. The first trenches T1 may be formed to pass through the active layer 106 and the buried insulating layer 104 in the vertical direction (the Z direction) and extend lengthwise in the second horizontal direction (the Y direction).

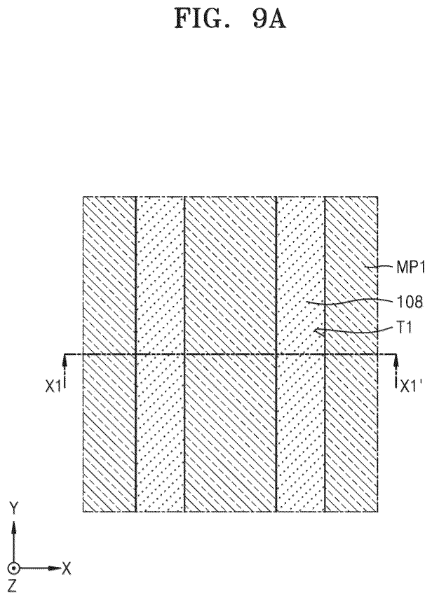

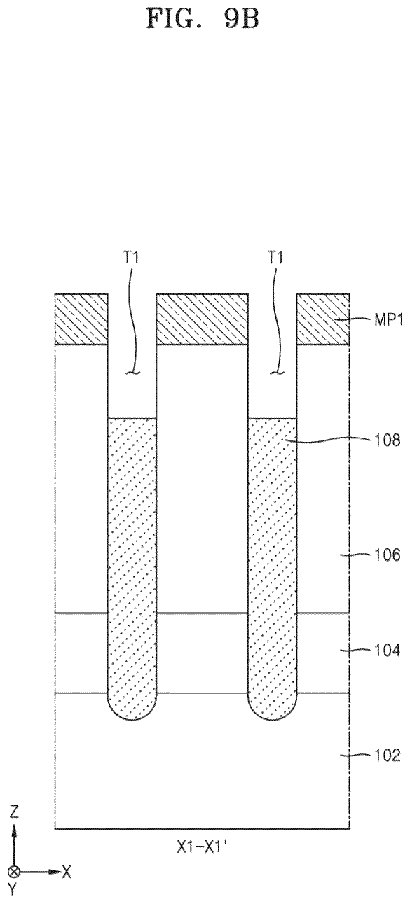

Referring to FIGS. 9A and 9B, a plurality of sacrificial films 108 respectively filling portions of the first trenches T1 in the resultant structure of FIGS. 8A and 8B may be formed.

The sacrificial films 108 may include a material having an etch selectivity with respect to the material of each of the active layer 106 and the mask pattern MPL. In one or more embodiments, the sacrificial films 108 may include, but not limited to, metal, metal nitride, or a combination thereof.

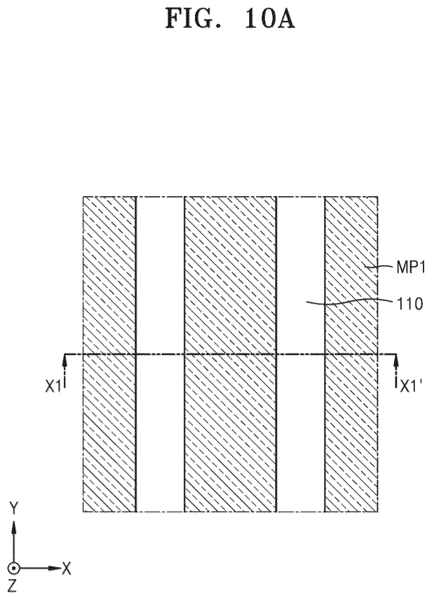

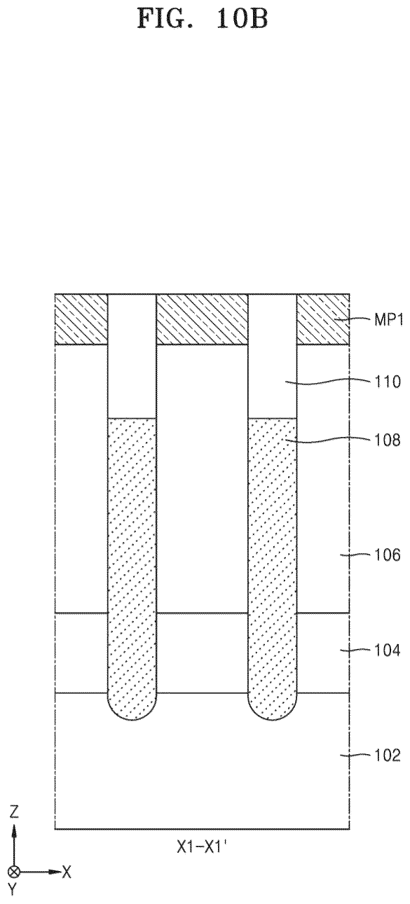

Referring to FIGS. 10A and 10B, a plurality of first capping insulating patterns 110 respectively filling the first trenches T1 respectively remaining on the sacrificial films 108 in the resultant structure of FIGS. 9A and 9B may be formed.

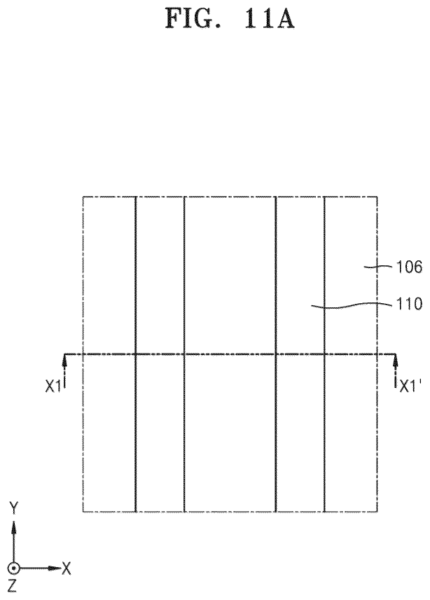

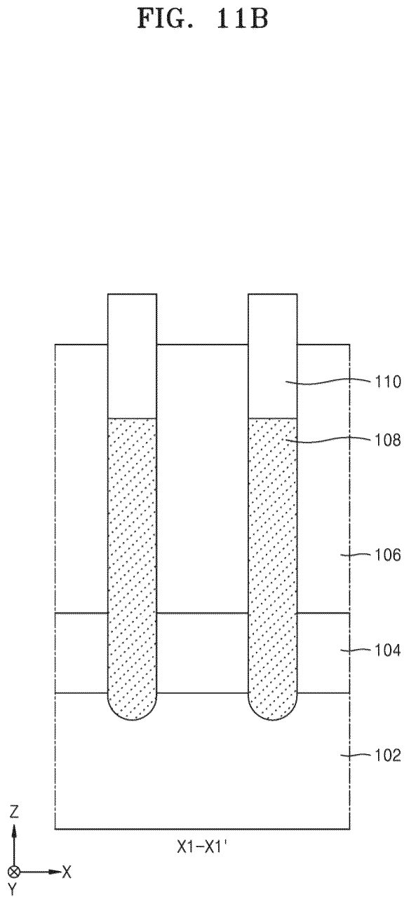

Referring to FIGS. 11A and 11B, the active layer 106 around the first capping insulating patterns 110 may be exposed by removing the mask pattern MP1 in the resultant structure of FIGS. 10A and 10B.

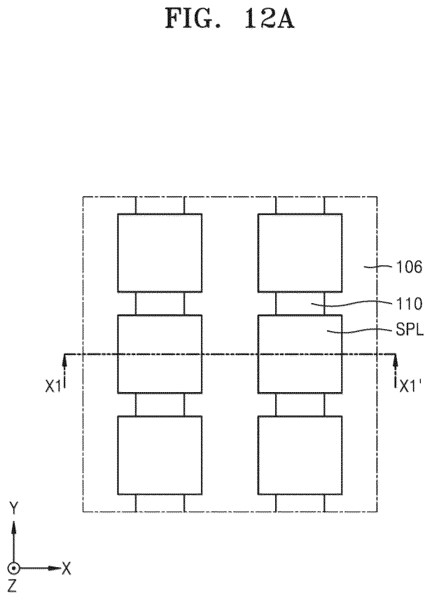

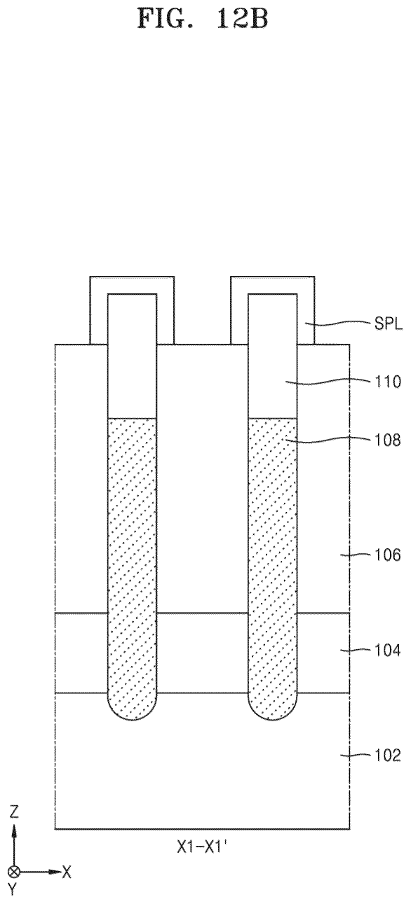

Referring to FIGS. 12A and 12B, a plurality of sacrificial spacer layers SPL each covering a portion of one of the first capping insulating patterns 110 and a portion of the active layer 106 around the portion of the one first capping insulating pattern 110 may be formed. Each of the sacrificial spacer layers SPL may include a silicon oxide film.

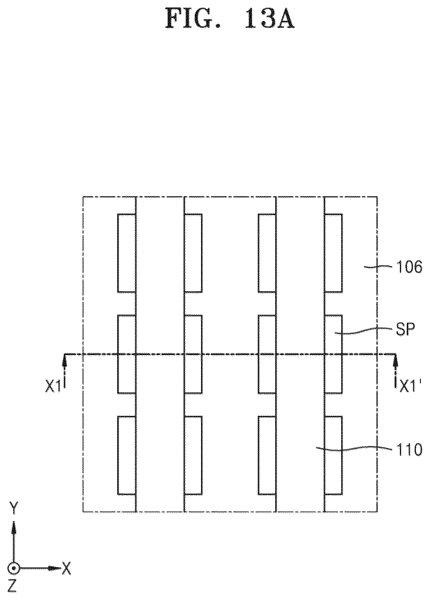

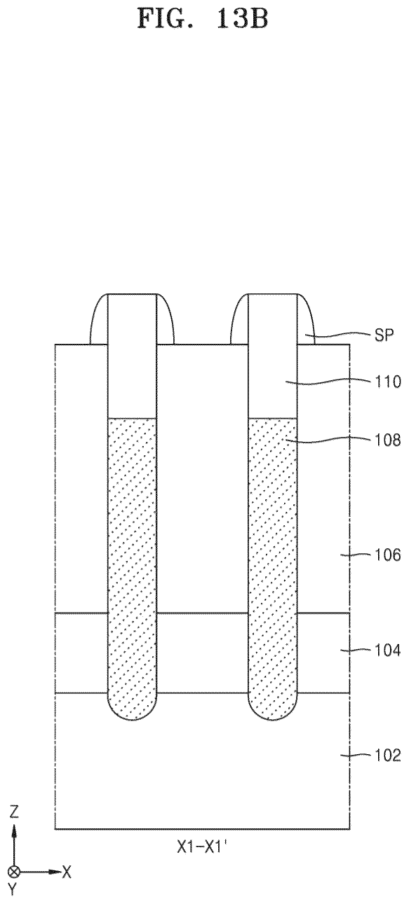

Referring to FIGS. 13A and 13B, a plurality of sacrificial spacers SP each covering opposite sidewalls of one of the first capping insulating patterns 110 in the first horizontal direction (the X direction) may be formed by etching back the sacrificial spacer layers SPL. Some portions of the active layer 106, which are adjacent to the first capping insulating patterns 110 may be covered with the sacrificial spacers SP.

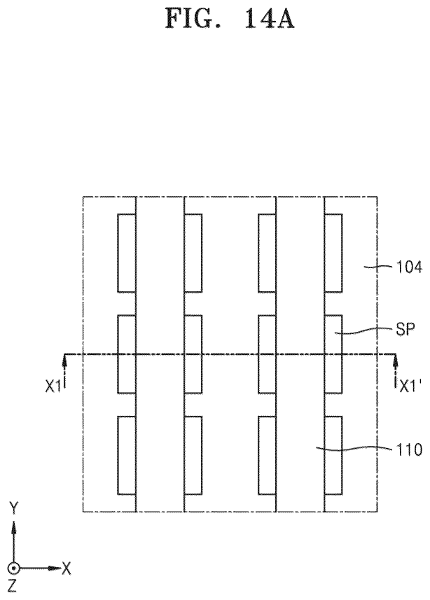

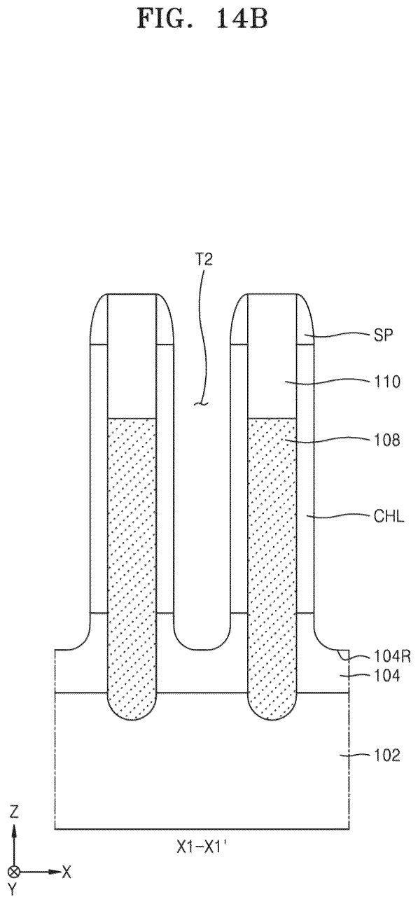

Referring to FIGS. 14A and 14B, a plurality of second trenches T2 may be formed by etching the active layer 106 by using the first capping insulating patterns 110 and the sacrificial spacers SP as etch masks.

As a result, the portions of the active layer 106 below the sacrificial spacers SP may remain as a plurality of vertical channel patterns CHL. The buried insulating layer 104 may be partially etched by excessive etching in the process of etching the active layer 106, so a plurality of recesses 104R respectively connected to the second trenches T2 may be formed in the top surface of the buried insulating layer 104.

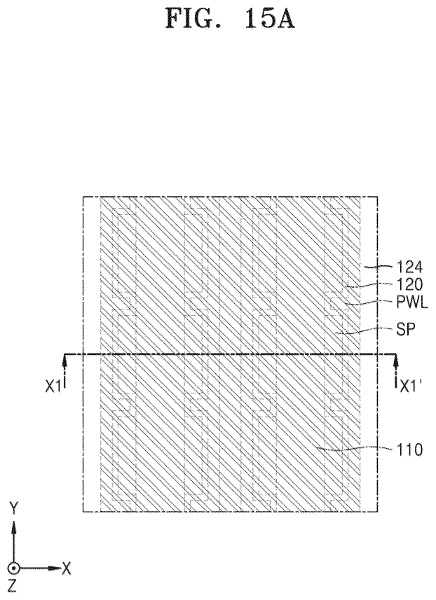

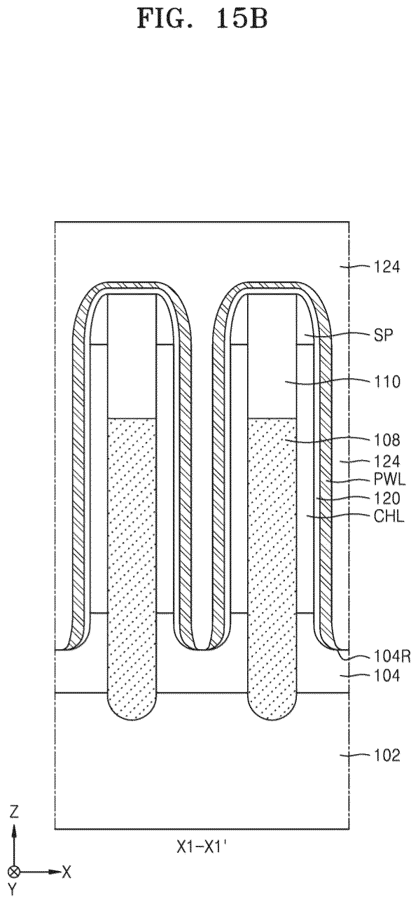

Referring to FIGS. 15A and 15B, a gate dielectric film 120 conformally covering the resultant structure of FIGS. 14A and 14B may be formed. After a conductive layer conformally covering the gate dielectric film 120 is formed, the conductive layer may be divided into a plurality of preliminary word lines PWL by partially etching the conductive layer in the recesses 104R of the buried insulating layer 104.

Subsequently, a sandwich pattern 124 filling the space above the preliminary word lines PWL may be formed. The sandwich pattern 124 may be formed to fill the space between the preliminary word lines PWL and cover the top surfaces of the preliminary word lines PWL. The material of the conductive layer may be the same as that of the word lines WL described above.

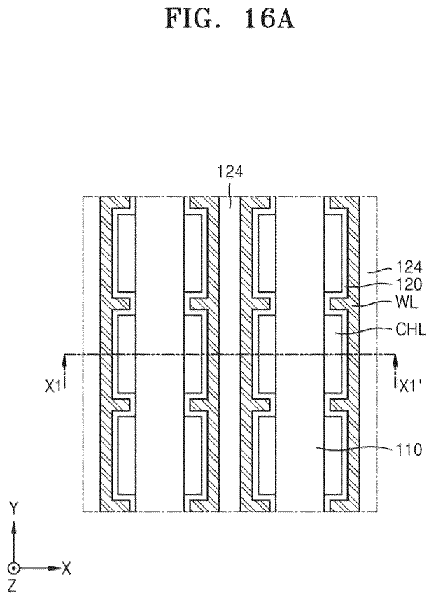

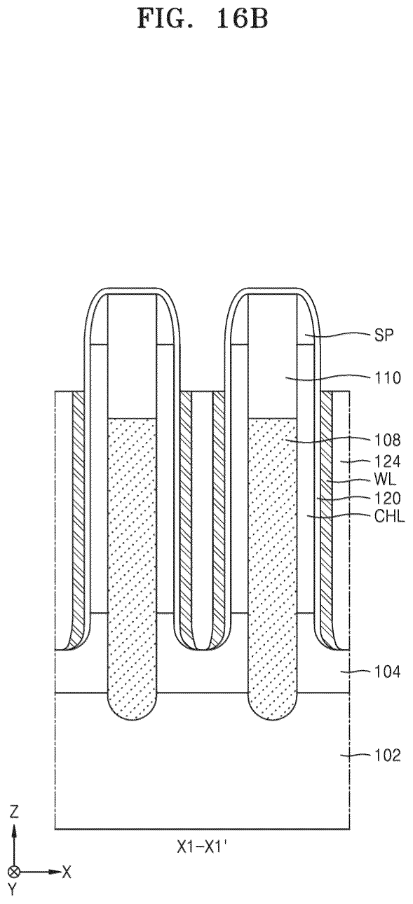

Referring to FIGS. 16A and 16B, portions of the preliminary word lines PWL may be exposed by removing an upper portion of the sandwich pattern 124 by etching back the sandwich pattern 124 in the resultant structure of FIGS. 15A and 15B, and a plurality of word lines WL may be formed by etching the exposed portions of the preliminary word lines PWL.

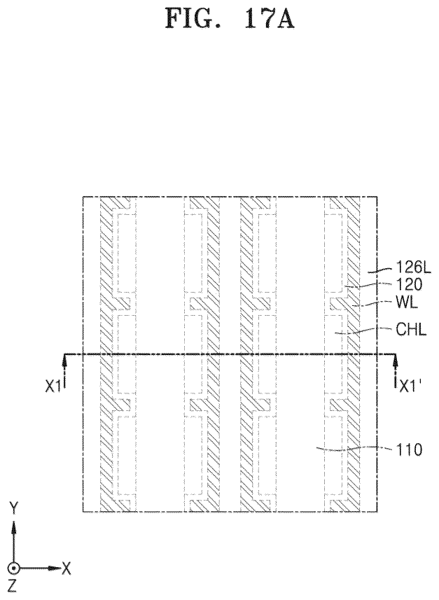

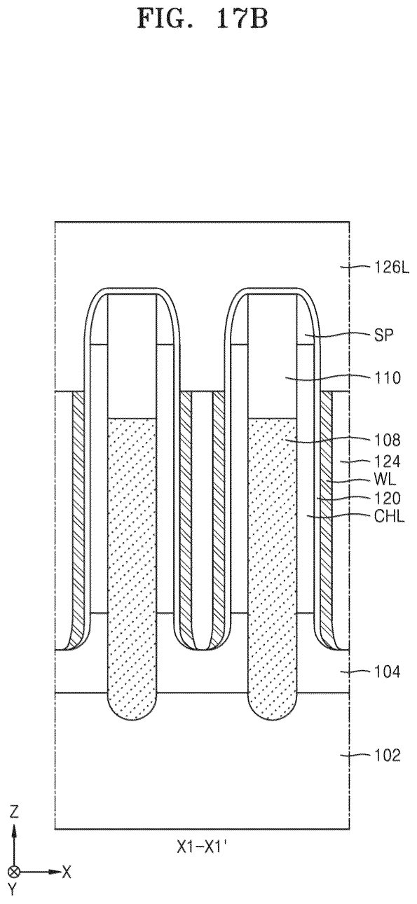

Referring to FIGS. 17A and 17B, a first buried insulating film 126L covering the resultant structure of FIGS. 16A and 16B may be formed. The material of the first buried insulating film 126L may be the same as that of the first buried insulating pattern 126 described above.

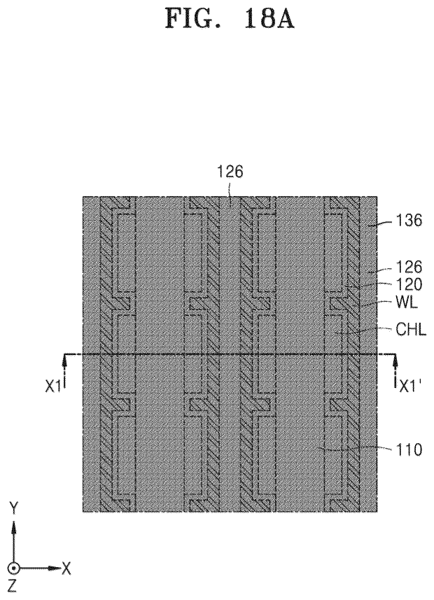

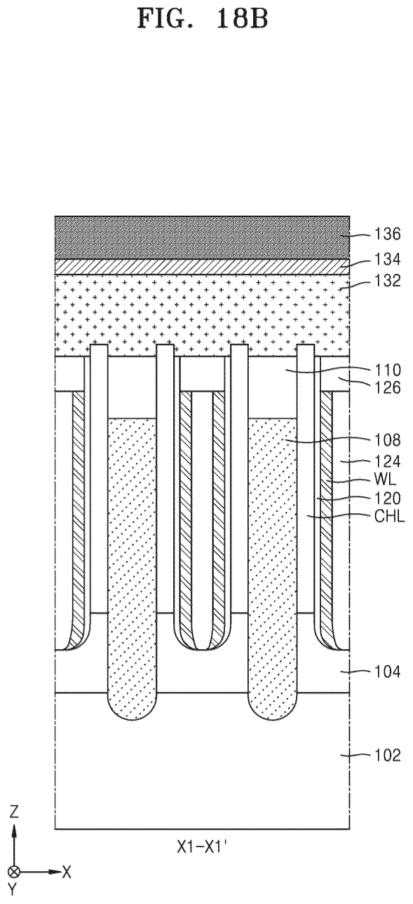

Referring to FIGS. 18A and 18B, the vertical channel patterns CHL may be exposed by performing planarization on the exposed top surface of the first buried insulating film 126L in the resultant structure of FIGS. 17A and 17B, and the first buried insulating pattern 126 may be formed from the first buried insulating film 126L.

In one or more embodiments, after the vertical channel patterns CHL are exposed, the height of the top of each of the first capping insulating patterns 110, the gate dielectric film 120, and the first buried insulating pattern 126 may be lowered. Accordingly, an upper portion of each of the vertical channel patterns CHL may be exposed.

Subsequently, a first conductive pattern 132, a second conductive pattern 134, and a third conductive pattern 136 may be sequentially stacked on the vertical channel patterns CHL. For example, the first conductive pattern 132 may include doped polysilicon, the second conductive pattern 134 may include metal silicide, and the third conductive pattern 136 may include metal, but embodiments are not limited thereto.

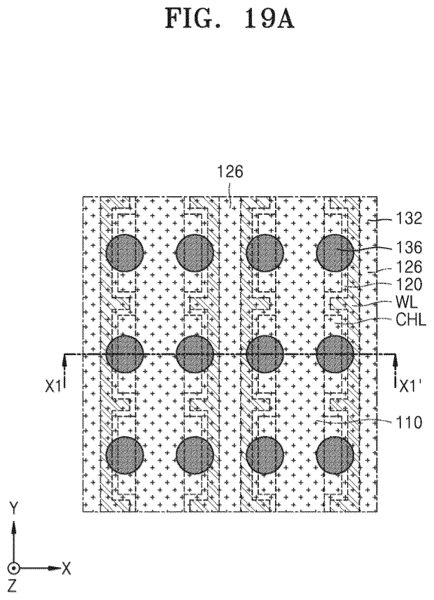

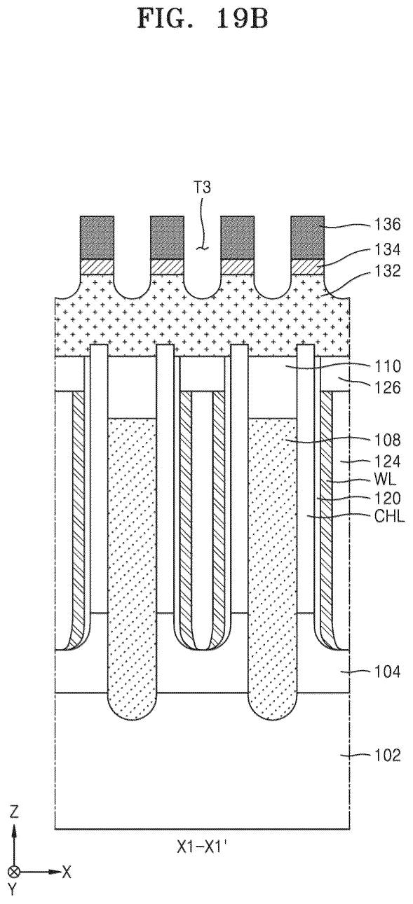

Referring to FIGS. 19A and 19B, a third trench T3 may be formed by partially etching each of the first conductive pattern 132, the second conductive pattern 134, and the third conductive pattern 136 by using, as an etch mask, a mask pattern on the resultant structure of FIGS. 18A and 18B

The third trench T3 may be formed to pass through the third conductive pattern 136 and the second conductive pattern 134 and a portion of the first conductive pattern 132 in the vertical direction (the Z direction). In a plan view, the third trench T3 may appear as one.

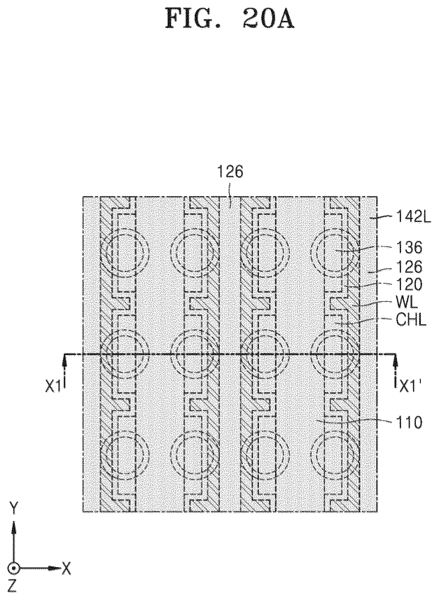

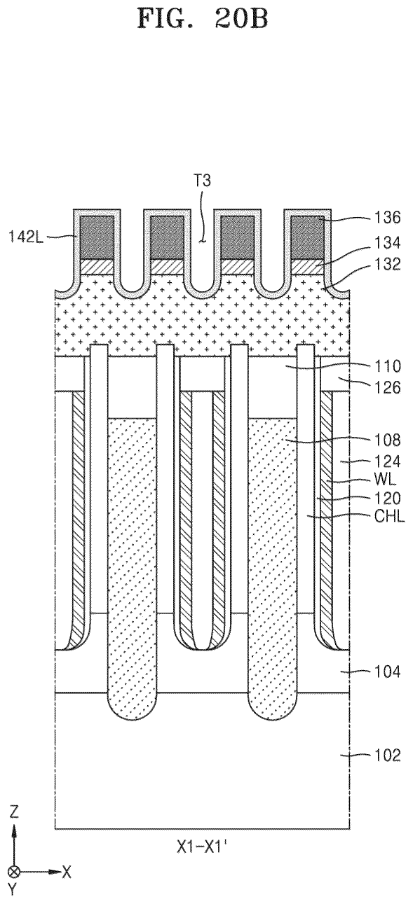

Referring to FIGS. 20A and 20B, the mask pattern may be removed from the resultant structure of FIGS. 19A and 19B, and a spacer forming layer 142L may be formed. The spacer forming layer 142L may be conformally formed on the inner wall of the third trench T3 and the top surface of the third conductive pattern 136.

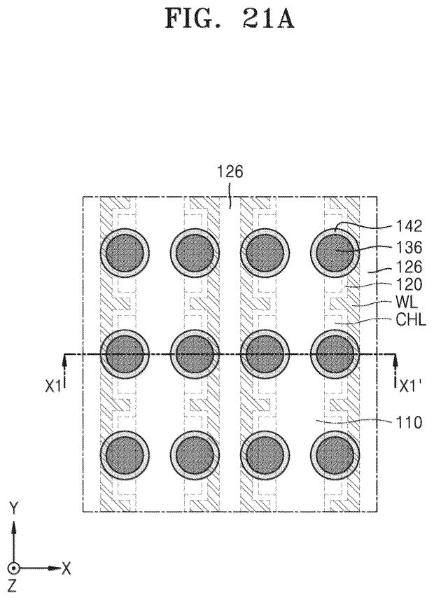

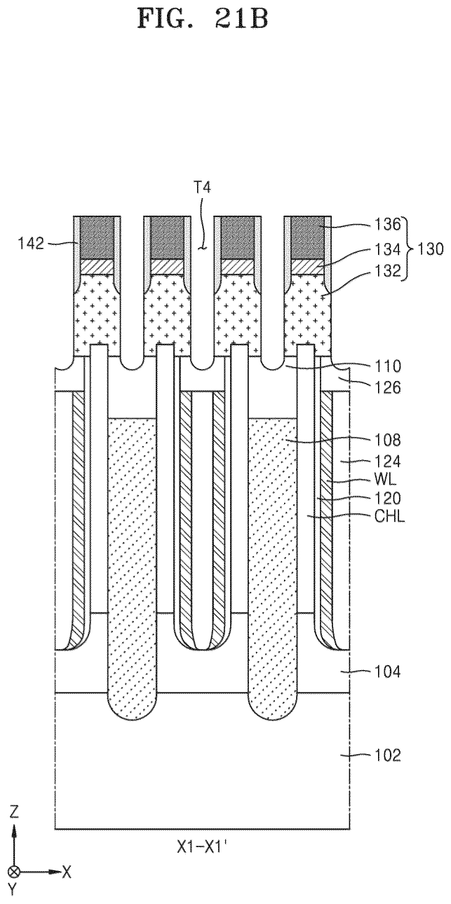

Referring to FIGS. 21A and 21B, a plurality of fourth trenches T4 may be formed by further etching the third trench T3 in the resultant structure of FIGS. 20A and 20B.

Each of the fourth trenches T4 may pass through the first conductive pattern 132 and a portion of one of the first capping insulating patterns 110 or the first buried insulating pattern 126 in the vertical direction (the Z direction). Accordingly, a plurality of insulating spacers 142 may be formed from the spacer forming layer 142L. The first conductive pattern 132, the second conductive pattern 134, and the third conductive pattern 136 may be node-separated from one another, thereby forming a plurality of contact plugs 130.

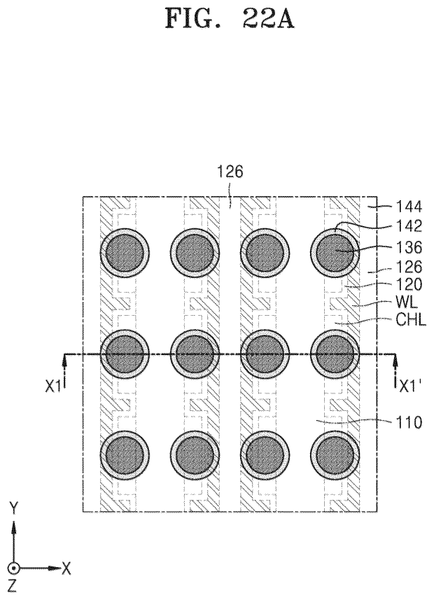

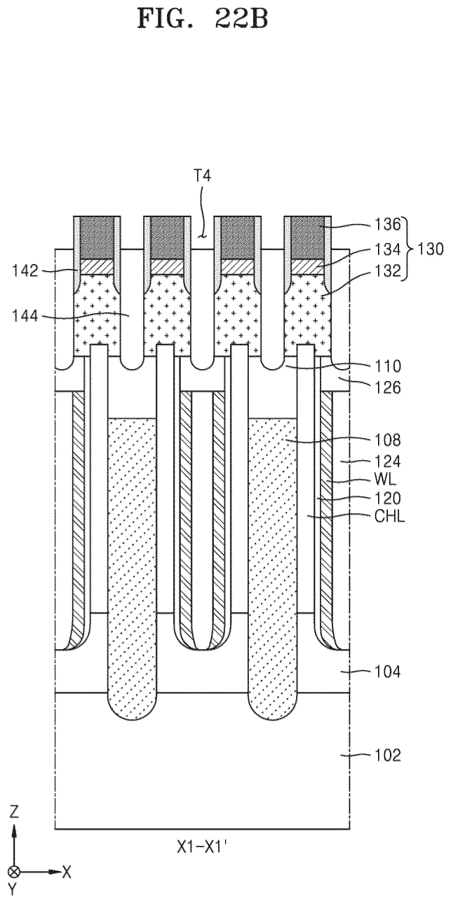

Referring to FIGS. 22A and 22B, a plurality of lower insulating patterns 144 respectively filling portions of the fourth trenches T4 in the resultant structure of FIGS. 21A and 21B may be formed. In one or more embodiments, the lower insulating patterns 144 may include a silicon oxide film.

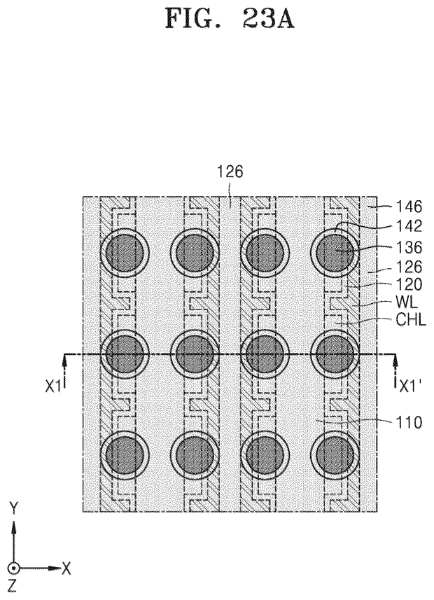

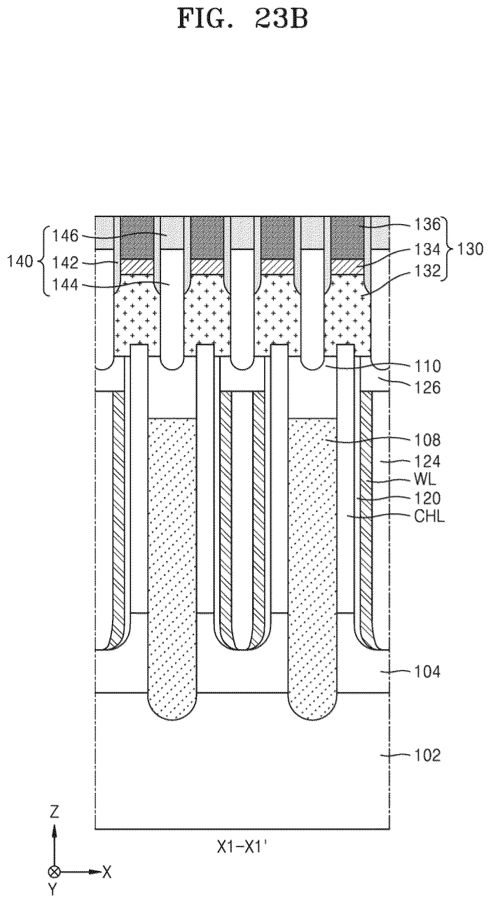

Referring to FIGS. 23A and 23B, an upper insulating pattern 146 filling the remaining portions of the fourth trenches T4 on the lower insulating patterns 144 in the resultant structure of FIGS. 22A and 22B may be formed.

Accordingly, the insulating spacers 142, the lower insulating patterns 144, and the upper insulating pattern 146 may form the isolation insulating structure 140. In one or more embodiments, the insulating spacers 142 and the upper insulating pattern 146 may include a silicon nitride film. In a plan view, the upper insulating pattern 146 may appear as one.

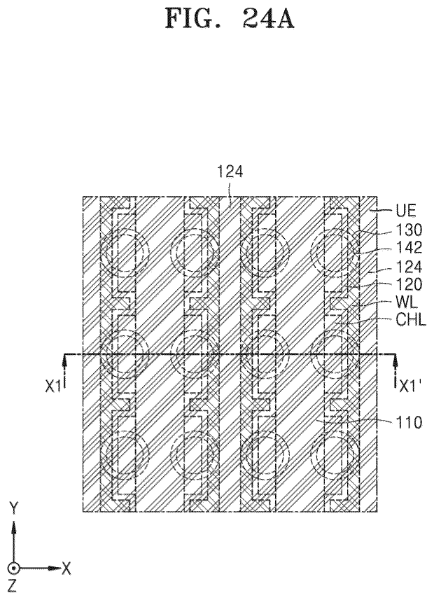

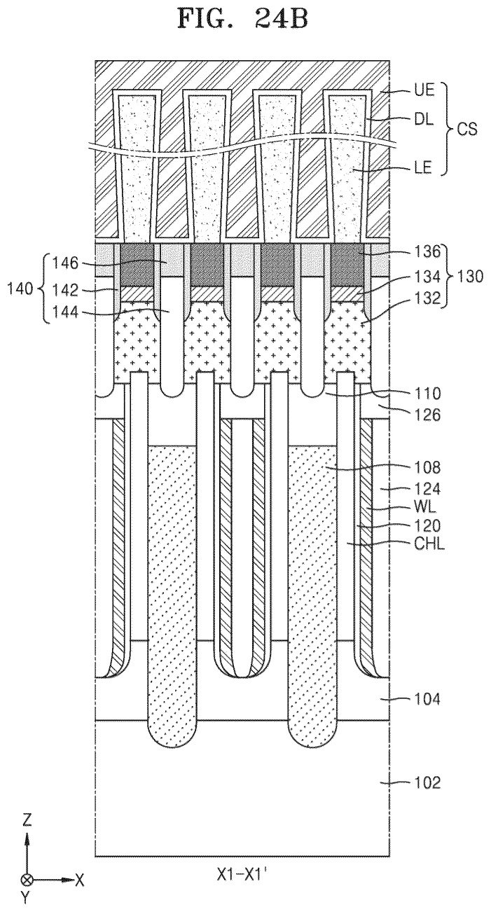

Referring to FIGS. 24A and 24B, a capacitor structure CS, which is connected to the contact plugs 130 and including a plurality of lower electrodes LE, a capacitor dielectric film DL, and an upper electrode UE, may be formed on the resultant structure of FIGS. 23A and 23B.

Referring to FIG. 25, the resultant structure of FIGS. 24A and 24B may be flipped such that the vertical direction (the Z direction) is reversed and the substrate 102 faces upwards in the vertical direction (the Z direction). A grinding process and a wet etching process may be sequentially performed on the substrate 102 from the exposed backside of the substrate 102 such that the buried insulating layer 104 and the sacrificial films 108 are exposed.

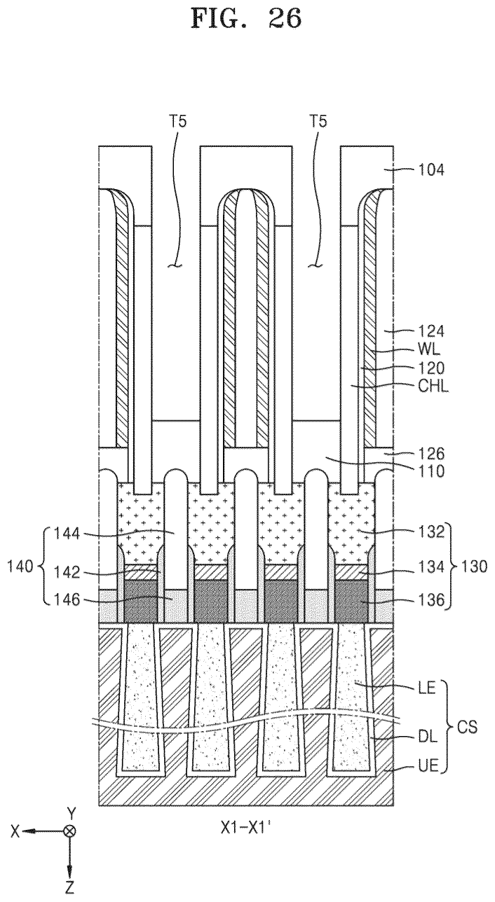

Referring to FIG. 26, the first capping insulating patterns 110 may be exposed by a plurality of fifth trenches T5 by removing the sacrificial films 108 from the resultant structure of FIG. 25.

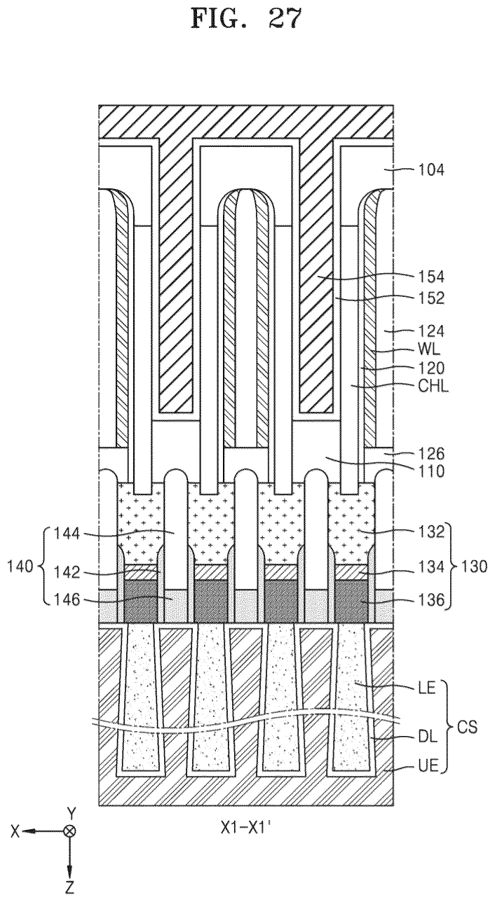

Referring to FIG. 27, a back gate dielectric film 152 may be formed to conformally cover the surfaces of the vertical channel patterns CHL and the first capping insulating patterns 110, which are exposed by the fifth trenches T5 in the resultant structure of FIG. 26, and a conductive layer 154 may be formed on the back gate dielectric film 152 to fill the remaining spaces of the fifth trenches T5.

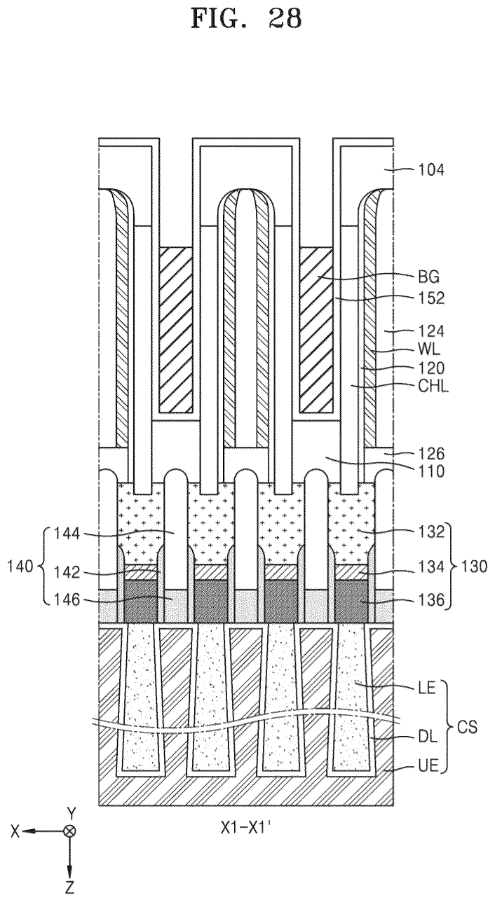

Referring to FIG. 28, a plurality of back gate electrodes BG may be formed from the conductive layer 154 by partially etching back the conductive layer 154 in the resultant structure of FIG. 27.

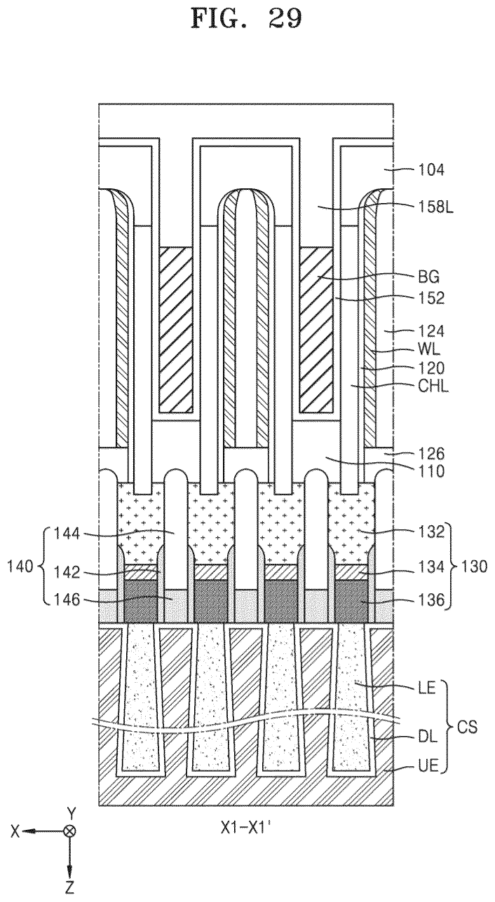

Referring to FIG. 29, a second capping insulating layer 158L covering the back gate electrodes BG in the resultant structure of FIG. 28 may be formed. The material of the second capping insulating layer 158L may be the same as the second capping insulating pattern 158 described above.

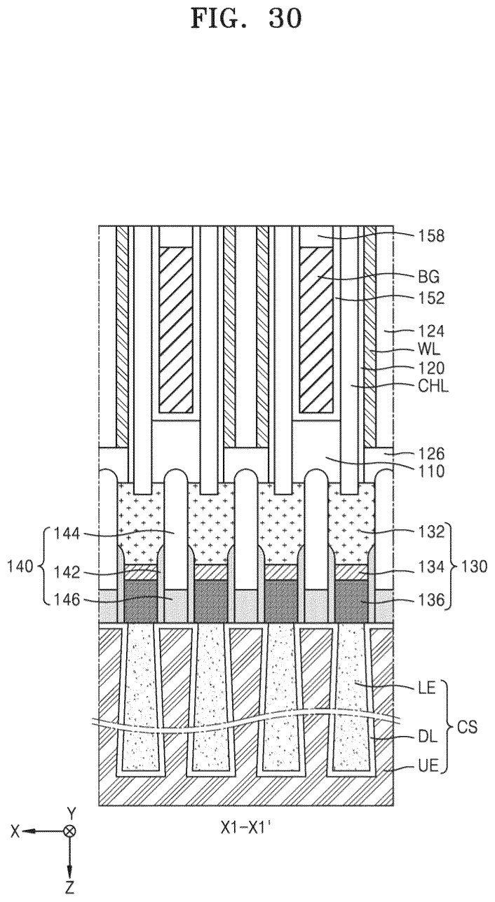

Referring to FIG. 30, the vertical channel patterns CHL may be exposed by performing planarization on the exposed surface of the second capping insulating layer 158L in the resultant structure of FIG. 29. As a result, the second capping insulating layer 158L may be divided into a plurality of second capping insulating patterns 158, and the exposed surface of each of the second capping insulating patterns 158, the word lines WL, and a plurality of sandwich patterns 124 may be coplanar with the exposed surfaces of the vertical channel patterns CHL.

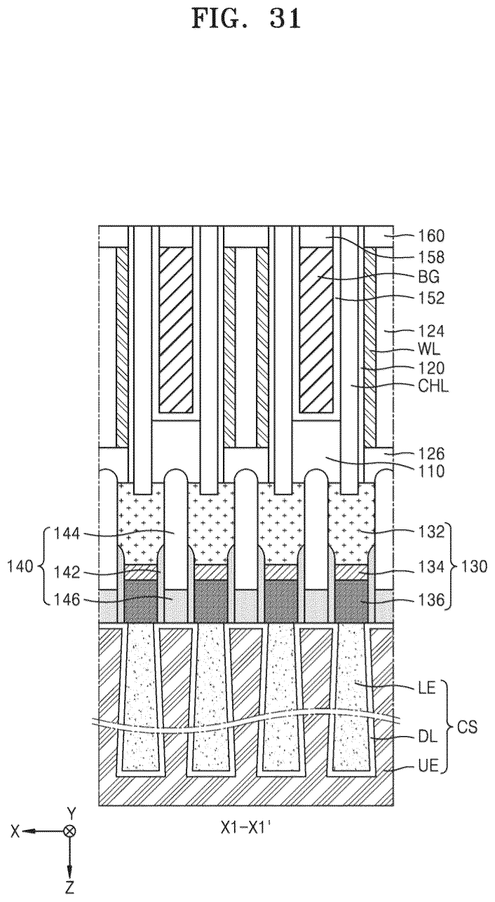

Referring to FIG. 31, space may be formed in upper portions of the word lines WL and the sandwich patterns 124 by partially removing the word lines WL and the sandwich patterns 124 from the exposed surfaces of the word lines WL and the sandwich patterns 124 in the resultant structure of FIG. 30, and a second buried insulating pattern 160 filling the space may be formed.

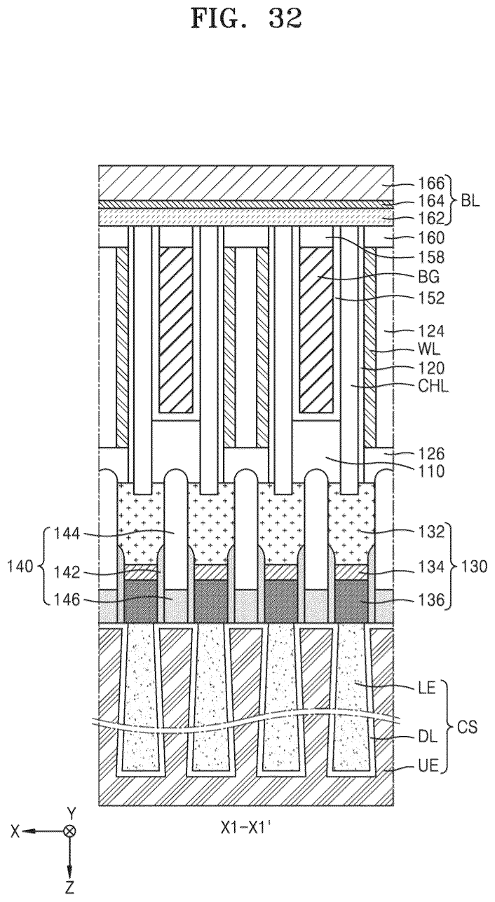

Referring to FIG. 32, a bit line BL sequentially including a first conductive line 162, a second conductive line 164, and a third conductive line 166 may be formed on the resultant structure of FIG. 31.

Subsequently, the resultant structure of FIG. 32 may be flipped such that the vertical direction (the Z direction) is reversed and the bit line BL faces downwards in the vertical direction (the Z direction). As a result, the semiconductor device 10 of FIGS. 1 to 3 may be manufactured.

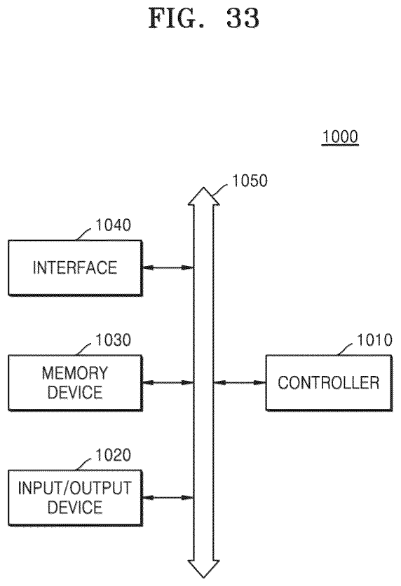

FIG. 33 is a block diagram of a system including a semiconductor device, according to one or more embodiments.

Referring to FIG. 33, a system 1000 may include a controller 1010, an input/output device 1020, a memory device 1030, an interface 1040, and a bus 1050.

The system 1000 may correspond to a mobile system or a system that transmits or receives information. In one or more embodiments, the mobile system may include a portable computer, a web tablet, a mobile phone, a digital music player, or a memory card.

The controller 1010 may control an execution program in the system 1000 and may include a microprocessor, a digital signal processor, a microcontroller, or the like.

The input/output device 1020 may be used to input data to or output data from the system 1000. The system 1000 may be connected to and may exchange data with an external device, e.g., a personal computer (PC) or a network, through the input/output device 1020. For example, the input/output device 1020 may include a touch screen, a touch pad, a keyboard, or a display.

The memory device 1030 may store data for the operation of the controller 1010 or data processed by the controller 1010. The memory device 1030 may include one of the semiconductor devices 10, 20, 30, 40, and 50 of the disclosure described above.

The interface 1040 may correspond to a data transmission passage between the system 1000 and an external device. The controller 1010, the input/output device 1020, the memory device 1030, and the interface 1040 may communicate with one another through the bus 1050.

While the disclosure has been particularly shown and described with reference to embodiments thereof, it will be understood that various changes in form and details may be made therein without departing from the spirit and scope of the following claims.

What is claimed is:

1. A semiconductor device comprising:
a bit line extending in a first horizontal direction;
a plurality of vertical channel patterns on the bit line and separated from each other in the first horizontal direction;
two word lines extending in a second horizontal direction between adjacent vertical channel patterns of the plurality of vertical channel patterns, the second horizontal direction intersecting the first horizontal direction;
a plurality of contact plugs contacting upper portions of the plurality of vertical channel patterns; and
an isolation insulating structure between the plurality of contact plugs, wherein the isolation insulating structure comprises:
a lower insulating pattern;
an upper insulating pattern on the lower insulating pattern; and
an insulating spacer on a sidewall of the upper insulating pattern and an upper sidewall of the lower insulating pattern,
wherein an upper width of each of the plurality of contact plugs in the first horizontal direction is less than a lower width of each of the plurality of contact plugs in the first horizontal direction, and
wherein an upper width of the isolation insulating structure in the first horizontal direction is greater than a lower width of the isolation insulating structure in the first horizontal direction.

2. The semiconductor device of claim 1, wherein a length of the lower insulating pattern in a vertical direction is greater than a length of the upper insulating pattern in the vertical direction, and
wherein a length of the insulating spacer in the vertical direction is greater than the length of the upper insulating pattern in the vertical direction.

3. The semiconductor device of claim 1, wherein a bottom surface of the lower insulating pattern is lower than top surfaces of the plurality of vertical channel patterns in a vertical direction, and
wherein the bottom surface of the lower insulating pattern is curved.

4. The semiconductor device of claim 1, wherein a top surface of the upper insulating pattern is at a same height as a top surface of the insulating spacer in a vertical direction, and
wherein a bottom surface of the insulating spacer is tapered.

5. The semiconductor device of claim 1, wherein the upper insulating pattern and the insulating spacer comprise a same material, and
wherein the lower insulating pattern comprises a different material than the upper insulating pattern.

6. The semiconductor device of claim 1, wherein each of the plurality of contact plugs comprises:
a first conductive pattern comprising doped polysilicon;
a second conductive pattern on the first conductive pattern and comprising metal silicide; and
a third conductive pattern on the second conductive pattern and comprising metal,
wherein a width of the second conductive pattern in the first horizontal direction is equal to a width of the third conductive pattern in the first horizontal direction, and
wherein a maximum width of the first conductive pattern in the first horizontal direction is greater than the width of the second conductive pattern and the width of the third conductive pattern in the first horizontal direction.

7. The semiconductor device of claim 6, wherein the first conductive pattern has a pitted shape and contacts top surfaces and sidewalls of the plurality of vertical channel patterns.

8. The semiconductor device of claim 6, wherein the first conductive pattern contacts the insulating spacer and the lower insulating pattern, and
wherein each of the second conductive pattern and the third conductive pattern contacts the insulating spacer and does not contact the lower insulating pattern.

9. The semiconductor device of claim 1, wherein each of the plurality of contact plugs comprises:
a first conductive pattern comprising metal silicide; and
a second conductive pattern on the first conductive pattern and comprising metal, and
wherein the insulating spacer contacts the second conductive pattern and does not contact the first conductive pattern.

10. The semiconductor device of claim 1, wherein each of the plurality of contact plugs comprises doped polysilicon,
wherein a top surface of the doped polysilicon is at a same height as a top surface of the upper insulating pattern in a vertical direction, and
wherein the doped polysilicon contacts the insulating spacer and the lower insulating pattern.

11. A semiconductor device comprising:
a bit line extending in a first horizontal direction;
a plurality of vertical channel patterns on the bit line and separated from each other in the first horizontal direction;
two word lines extending in a second horizontal direction between adjacent vertical channel patterns of the plurality of vertical channel patterns, the second horizontal direction intersecting the first horizontal direction;
a plurality of contact plugs contacting upper portions of the plurality of vertical channel patterns; and
an isolation insulating structure between the plurality of contact plugs, wherein the isolation insulating structure comprises:
a lower insulating pattern having a first width in the first horizontal direction; and
an upper insulating pattern on the lower insulating pattern and having a second width that is greater than the first width,
wherein a bottom surface of the lower insulating pattern is curved.

12. The semiconductor device of claim 11, wherein each of the plurality of contact plugs comprises:
a first conductive pattern comprising doped polysilicon;
a second conductive pattern on the first conductive pattern and comprising metal silicide; and
a third conductive pattern on the second conductive pattern and comprising metal,
wherein the first conductive pattern contacts the lower insulating pattern and the upper insulating pattern, and
wherein each of the second conductive pattern and the third conductive pattern contacts the upper insulating pattern and does not contact the lower insulating pattern.

13. The semiconductor device of claim 12, wherein a maximum width of the second conductive pattern in the first horizontal direction is equal to a maximum width of the third conductive pattern in the first horizontal direction, and
wherein a maximum width of the first conductive pattern in the first horizontal direction is greater than the width of the second conductive pattern and the width of the third conductive pattern in the first horizontal direction.

14. The semiconductor device of claim 13, wherein a top surface of the first conductive pattern is higher than a top surface of the lower insulating pattern in a vertical direction, and
wherein a bottom surface of the first conductive pattern is higher than a bottom surface of the lower insulating pattern in the vertical direction.

15. The semiconductor device of claim 11, wherein the lower insulating pattern comprises silicon oxide, and
wherein the upper insulating pattern comprises silicon nitride.

16. A semiconductor device comprising:
a bit line extending in a first horizontal direction;
a plurality of vertical channel patterns on the bit line and separated from each other in the first horizontal direction;
two word lines extending in a second horizontal direction between first vertical channel pattern and second vertical channel pattern of the plurality of vertical channel patterns, the first vertical channel pattern and the second vertical channel pattern being adjacent, the second horizontal direction intersecting the first horizontal direction;
a back gate electrode extending in the second horizontal direction between the second vertical channel pattern and a third vertical channel pattern of the plurality of vertical channel patterns, the second vertical channel pattern and the third vertical channel pattern being adjacent;
a plurality of contact plugs contacting upper portions of the plurality of vertical channel patterns;
an isolation insulating structure between the plurality of contact plugs; and
a capacitor structure on the plurality of contact plugs and the isolation insulating structure,
wherein the plurality of contact plugs comprises:
a first conductive pattern comprising doped polysilicon;
a second conductive pattern on the first conductive pattern and comprising metal silicide; and
a third conductive pattern on the second conductive pattern and comprising metal, and
wherein the isolation insulating structure comprises:
a lower insulating pattern;
an upper insulating pattern on the lower insulating pattern; and
an insulating spacer on a sidewall of the upper insulating pattern and an upper sidewall of the lower insulating pattern.

17. The semiconductor device of claim 16, wherein an upper width of each of the plurality of contact plugs in the first horizontal direction is less than a lower width of each of the plurality of contact plugs in the first horizontal direction, and
wherein an upper width of the isolation insulating structure in the first horizontal direction is greater than a lower width of the isolation insulating structure in the first horizontal direction.

18. The semiconductor device of claim 17, wherein a distance between the first vertical channel pattern and the second vertical channel pattern in the first horizontal direction is greater than the upper width and the lower width of the isolation insulating structure.

19. The semiconductor device of claim 16, wherein a bottom surface of the lower insulating pattern is lower than top surfaces of the plurality of vertical channel patterns in a vertical direction,
wherein a top surface of the upper insulating pattern is at a same height as a top surface of the insulating spacer in the vertical direction, and
wherein a bottom surface of the upper insulating pattern is higher than a bottom surface of the insulating spacer in the vertical direction.

20. The semiconductor device of claim 19, wherein a vertical distance from the bottom surface of the lower insulating pattern to top surfaces of the two word lines is less than a vertical distance from the bottom surface of the lower insulating pattern to a top surface of the back gate electrode.
